(19) United States
(12) Patent Application Publication
(10) Pub. No.: US 2017/0301817 A1
(43) Pub. Date: Oct. 19, 2017

(54) GERMANIUM DEVICES ON AMORPHOUS SUBSTRATES

(71) Applicants: BRIAN PEARSON, NEWPORT BEACH, CA (US); JURGEN MICHEL, ARLINGTON, MA (US); LIONEL KIMERLING, CONCORD, MA (US)

(72) Inventors: BRIAN PEARSON, NEWPORT BEACH, CA (US); JURGEN MICHEL, ARLINGTON, MA (US); LIONEL KIMERLING, CONCORD, MA (US)

(21) Appl. No.: 15/487,182

(22) Filed: Apr. 13, 2017

Related U.S. Application Data
(60) Provisional application No. 62/321,957, filed on Apr. 13, 2016.

(51) Int. Cl. H01L 31/108; H01L 27/144; H01L 31/028; H01L 31/18

(52) U.S. Cl. CPC H01L 31/1085; H01L 31/1808; H01L 27/1443; H01L 31/028

(57) ABSTRACT

A germanium metal-semiconductor-metal (MSM) photodetector is fabricated by growing crystalline germanium from an amorphous silicon seed, supported by an amorphous substrate, at a temperature of about 450° C. In this fabrication, crystalline Ge is grown via selective deposition in geometrically confined channels, where amorphous silicon is disposed as the growth seed. Ge growth extends from the growth seed along the channels to a lithographically defined trench. The Ge emerging out of the channels includes crystalline grains that coalesce to fill the trench, forming a Ge strip that can be used as the active area of a photodetector. One or more Schottky contacts can be formed by a thin tunneling layer (e.g., Al₂O₃) deposited on the Ge strip and metal contracts formed on the tunneling layer.

### CROSS-REFERENCES TO RELATED APPLICATIONS

This application claims priority to U.S. Application No. 62/321,957, filed Apr. 13, 2016, entitled “GERMANIUM PHOTODETECTOR ON AMORPHOUS SUBSTRATES,” which is hereby incorporated herein by reference in its entirety.

### GOVERNMENT SUPPORT

This invention was made with Government support under Grant No. DE-AR0000472 awarded by the Department of Energy. The Government has certain rights in the invention.

### BACKGROUND

A typical optical interconnect includes four components: a light source to provide an optical carrier, a modulator to encode the optical carrier with digital information (e.g., by switching the light on and off), a waveguide to guide the modulated optical carrier, and a detector to convert the modulated optical carrier into an electrical signal.

Compared to metal interconnects that are conventionally used in silicon complementary metal oxide semiconductor (CMOS) devices, optical interconnects have several advantages. First, optical interconnects can reduce or eliminate heat dissipation issues in metal interconnects because photons do not generate heat when propagating through the interconnects. In addition, optical waveguides have a very high data capacity and can transmit data at much higher bandwidths than metal interconnects. Optical interconnects also allows high levels of multiplexing, where multiple discrete signals can be transmitted at different wavelengths along a single waveguide, i.e., wavelength division multiplexing (WDM).

One issue with optical interconnects is their relatively large sizes. For example, an active region in a modulator or detector (e.g., germanium or silicon regions) usually has a length of about 50 μm to about 80 μm and a width of about 0.5 μm to 1 μm. In contrast, an electrical device can have features sizes in the tens of nanometers range. Therefore, the introduction of optical interconnects may consume much valuable space on a silicon wafer.

To solve this issue, optical interconnects can be integrated into the final device via back-end-of-line (BEOL) processing. In typical BEOL processing, components, such as metal wires and other interconnects, are taken off of the silicon wafer and integrated at a level above the electronics level on the silicon wafer. This can introduce all of the benefits optical interconnects without sacrificing any of the valuable real estate on the crystalline silicon wafer.

However, there remain several challenges to integrate optical interconnects using BEOL processing. As described above, optical interconnects typically have a single-crystalline active region to achieve desired electrical and optical properties. Single-crystalline devices are usually fabricated using ultra-high vacuum chemical vapor deposition (UHVCVD), which epitaxially grows single-crystalline components using a crystalline substrate as the seed. The growth is typically carried out at high temperatures. For example, germanium is usually grown at about 600° C. to about 700° C. and may be annealed at temperatures up to 900° C. in order to reduce the threading dislocation density.

In contrast, when the devices are grown above the substrate in BEOL processing, there is no longer a crystalline seed to grow single-crystalline films epitaxially. In addition, electronic components and metal interconnects are already fabricated before BEOL processing is carried out. The high temperature typically used in epitaxial growth of single-crystalline films can degrade these electronics and interconnects via, for example, dopant diffusion and silicidation of metal contacts.

### SUMMARY

Embodiments of the present technology generally relate to germanium photodetectors fabricated on amorphous substrates. In one example, an apparatus includes a first strip made of crystalline germanium and extending along a first direction. The apparatus also includes at least one second strip made of germanium and extending along a second direction different from the first direction. The at least one second strip has a first end in contact with the first strip and a second end opposite the first end. A growth seed of amorphous silicon is disposed at the second end of the second strip to grow the at least one second strip and at least a portion of the first strip. The apparatus also includes a first electrode disposed on the first strip and a second electrode disposed on the first strip.

In another example, an apparatus includes a strip of crystalline germanium extending along a first direction. The strip has a plurality of grain boundaries distributed along the first direction. The apparatus also includes a first electrode disposed above a first grain boundary in the plurality of grain boundaries and a second electrode disposed on the strip.

In yet another example, a method of growing crystalline germanium on amorphous silicon incudes forming a channel structure in a SiO₂ layer. The channel structure includes a trench along a first direction in the SiO₂ layer and an array of seed channels extending from the trench and along a second direction different from the first direction. Each seed channel has a first end coupled to the trench and a respective growth seed disposed at a second end opposite the first end. The respective growth seed includes amorphous silicon. The method also includes growing the crystalline germanium in the trench based on at least in part on the respective growth seed in each seed channel.

It should be appreciated that all combinations of the foregoing concepts and additional concepts discussed in greater detail below (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein. It should also be appreciated that terminology explicitly employed herein that also may appear in any disclosure incorporated by reference should be accorded a meaning most consistent with the particular concepts disclosed herein.

### BRIEF DESCRIPTION OF THE DRAWINGS

The skilled artisan will understand that the drawings primarily are for illustrative purposes and are not intended to limit the scope of the inventive subject matter described herein. The drawings are not necessarily to scale; in some instances, various aspects of the inventive subject matter disclosed herein may be shown exaggerated or enlarged in the drawings to facilitate an understanding of different features. In the drawings, like reference characters generally refer to like features (e.g., functionally similar and/or structurally similar elements).

FIGS. 1A and 1B show a side view and a top view, respectively, of a germanium detector including aligned arrays of amorphous silicon seeds and fabricated via processes compatible with back-end-of-line (BEOL) processing.

FIGS. 2A and 2B show a side view and a top view, respectively, of a germanium detector including staggered arrays of amorphous silicon seeds.

FIGS. 3A-3C illustrate a method of growing crystalline germanium from a confined channel using amorphous silicon as a growth seed.

FIG. 4 is a plan-view scanning electron microscope (SEM) image of a germanium grain fabricated using the method illustrates in FIGS. 3A-3C.

FIG. 5 shows the calculated number of Ge grains emerging out of a channel as a function of the dimensions of the channel.

FIGS. 6A-6J illustrate a method of fabricating an active region of a Ge photodetector on an amorphous substrate.

FIG. 7 shows a plan-view SEM image of a lithographically-defined trench filled with Ge grains that are grown using the method illustrated in FIGS. 6A-6I.

FIG. 8 shows calculated growth time as a function of the pitch of growth channels used in the method illustrated in FIGS. 6A-6I.

FIGS. 9A-9G illustrate a method of fabricating an active region of a Ge photodetector using SiN for channel formation.

FIG. 10 shows a schematic of a Ge metal-semiconductor-metal (MSM) photodetector including an interlayer of amorphous silicon and HfO₂.

FIG. 11 shows measured dark currents as a function of voltage of a photodetector including an interlayer of amorphous silicon and HfO₂.

FIG. 12 shows an Arrhenius plot of the dark I-V measurements shown in FIG. 11 to estimate the Schottky barrier height of the photodetector used in FIG. 11.

FIG. 13 shows a schematic of a Ge MSM photodetector including an interlayer made of Al₂O₃ to form Schottky contacts.

FIG. 14 shows dark I-V measurements at a variety of different temperatures from about 30° C. to about 160° C. in a photodetector including an interlayer made of Al₂O₃ to form Schottky contacts.

FIG. 15 shows an Arrhenius plot of the dark I-V measurements taken in FIG. 14 at a bias voltage of about 0.5 V to estimate the Schottky barrier height of the photodetector used in FIG. 14.

FIG. 16 is a plot showing calculated Schottky Barrier height as a function of bias voltages in the photodetector used in FIG. 14.

FIG. 17 shows dark I-V measurements before and after annealing in a photodetector including an interlayer made of Al₂O₃ to form Schottky contacts.

FIGS. 18A and 18B illustrate a method to form Schottky contacts on Ge surface with improved protection of the Ge surface.

FIG. 19A shows an SEM image of a trench filled with crystalline Ge after chemical and mechanical planarization (CMP).

FIG. 19B shows an SEM image of the structure shown in FIG. 19A immediately after post-CMP cleaning in dilute H₂SO₄ and HF.

FIG. 20 shows measured dark I-V curves for a 75 μm long MSM photodetector with a contact separation of 2 μm.

FIG. 21 shows measured responsivity of MSM photodetectors grown on geometrically confined structures on amorphous substrates.

### DETAILED DESCRIPTION

Overview

To make optical interconnects compatible with BEOL processing, apparatus, systems, and methods described herein grow germanium (Ge) on an amorphous seed at temperatures substantially equal to or less than 450° C. In this technique, crystalline Ge is grown via selective deposition in geometrically confined channels, where amorphous silicon is disposed as the growth seed. Ge growth extends from the growth seed along the channels that are connected to a lithographically defined trench. The Ge emerging out of the channels includes crystalline grains that coalesce to fill the trench, forming a Ge strip that can be used as the active area of a photodetector.

One or more Schottky contacts can be formed by a thin tunneling layer (e.g., Al₂O₃) deposited on the Ge strip and metal contracts formed on the tunneling layer. These Schottky contacts and the crystalline Ge strip can function as a metal-semiconductor-metal (MSM) photodetector. The fabrication process is fully compatible with BEOL processing constraints and therefore can be used to integrate optical interconnects above the electronics level, thereby saving valuable space on the silicon wafer.

Germanium Photodetectors Fabricated On Amorphous Substrates

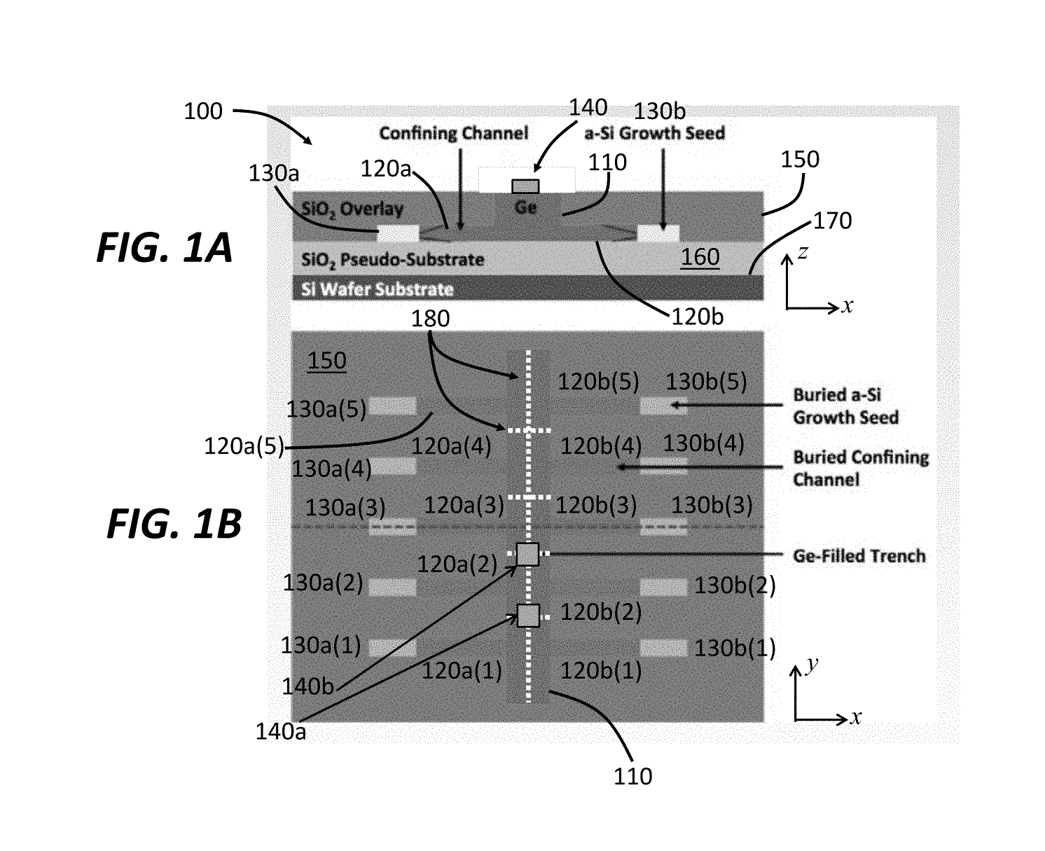

FIGS. 1A and 1B show a side view and a top view, respectively, of a germanium detector 100 fabricated via processes compatible with back-end-of-line (BEOL) processing. The detector 100 includes a main strip 110 extending along a first direction and made of crystalline Ge as the active detection region. A first array of side strips 120a (including strips 120a(1), 120a(2), 120a(3), 120a(4), and 120a(5)) is disposed on one side of the main strip 110 and a second array of side strips 120b (including strips 120b(1), 120b(2), 120b(3), 120b(4), and 120b(5)) is disposed on the opposite side of the main strip 110. The side strips 120a and 120b extend along a second direction different from the first direction of the main strip 110. Each side strip 120a/b(i), i=1, 2, . . . , 5, is fabricated from a respective growth seed 130a/b(i) including amorphous silicon in a channel defined in a SiO₂ overlay layer 150. Electrodes 140a and 140b (collectively referred to as electrodes 140) are disposed on the main strip 110 to form Ge detectors. The main strip 110 and the side strips 120a and 120b are disposed on an amorphous substrate 160 (e.g., SiO₂), which in turn can be disposed on a Si wafer 170.

The crystalline Ge in the main strip 110 is formed by coalescing Ge emerging out of each channel where the side strips 120b and 120a are formed. The regions where Ge grains from different channels meet form grain boundaries 180, as indicated by dashed lines in FIG. 1B. In the x direction, a grain boundary exists approximately in the middle of the main strip 110. In the y direction, grain boundaries exist approximately in the middle between two adjacent side strips. In some cases, the electrodes 140 are disposed right above the grain boundaries 180 (e.g., FIG. 1B). In some cases, one electrode 140a can be disposed above the grain boundary and the other electrode 140b can be disposed above the same grain at a location before a neighboring grain boundary.

The dimensions of the main strip 110 depend on several factors, including the desired size of the active region in the photodetector and the constraints on fabrication (e.g., a larger dimension usually takes a longer time to fabricate). The height of the main strip 110 (i.e., the dimension along the z direction, see FIG. 1A) can be about 100 nm to 2 μm (e.g., about 100 nm, about 200 nm, about 300 nm, about 500 nm, about 1 μm, or about 2 μm, including any values and sub ranges in between).

The width of the main strip 110 (i.e., the dimension along the x direction, see FIG. 1B) can be about 100 nm to about 2 μm (e.g., about 100 nm, about 200 nm, about 300 nm, about 500 nm, about 750 nm, about 1 μm, about 1.25 μm, about 1.5 μm, about 1.75 μm, or about 2 μm, including any values and sub ranges in between).

The length of the main strip 110 (i.e., the dimension along they direction) depends on the number of growth seeds 130a and 130b used in the fabrication. For example, the length of the main strip 110 can be about 2 μm to about 500 μm (e.g., about 2 μm, about 5 μm, about 10 μm, about 20 μm, about 50 μm, about 100 μm, about 200 μm, or about 500 μm, including any values and sub ranges in between).

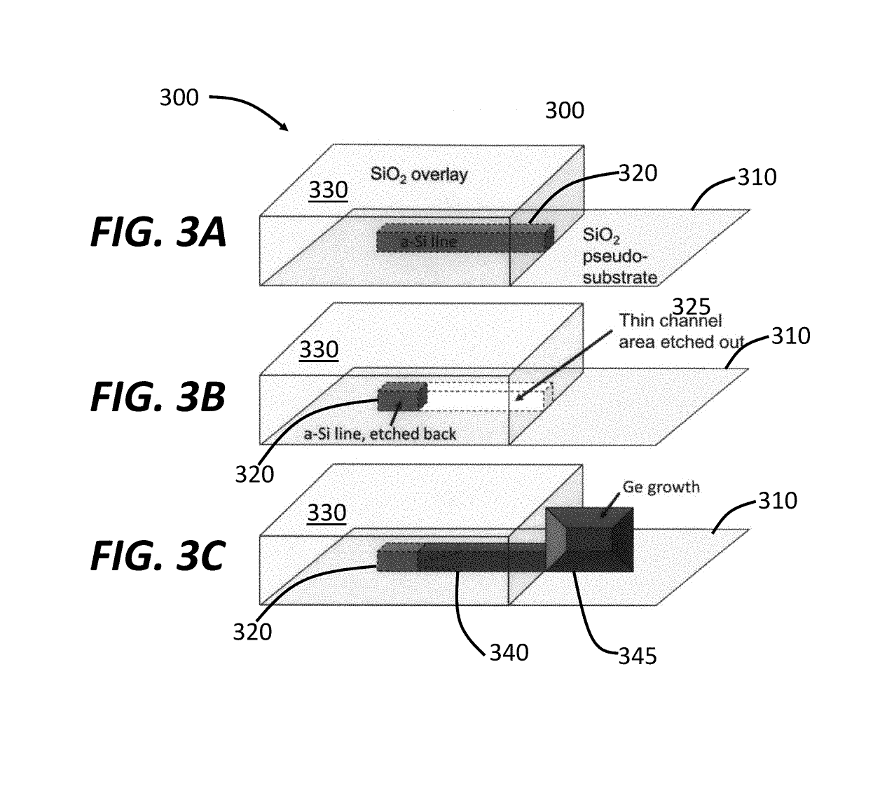

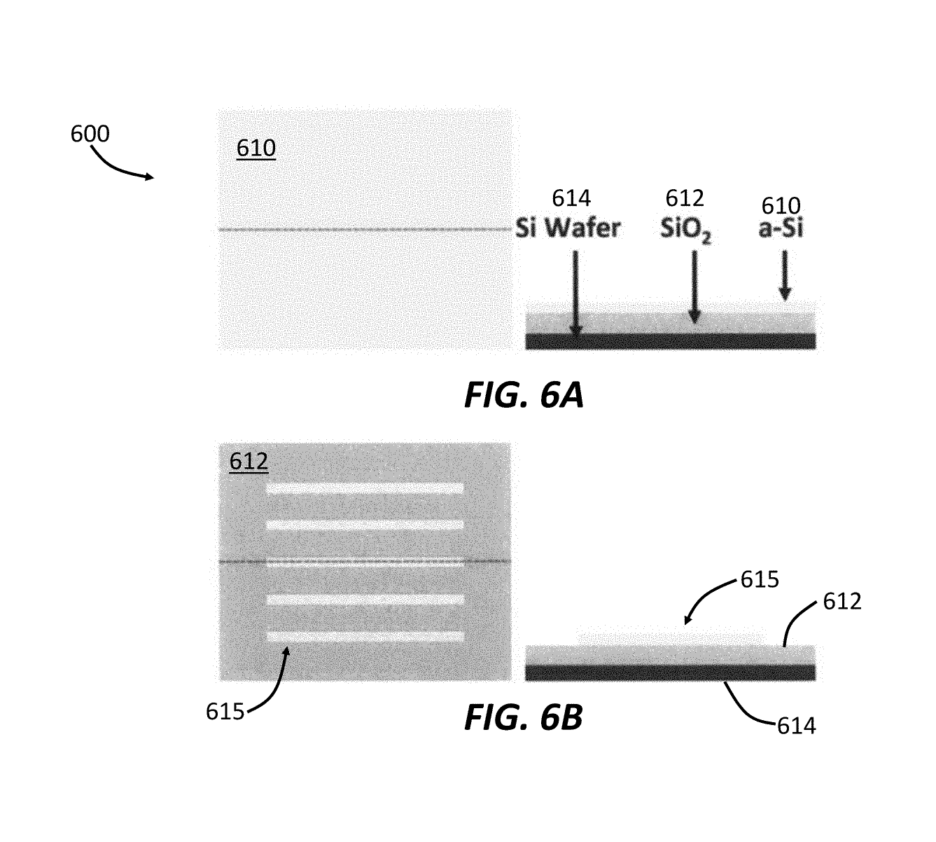

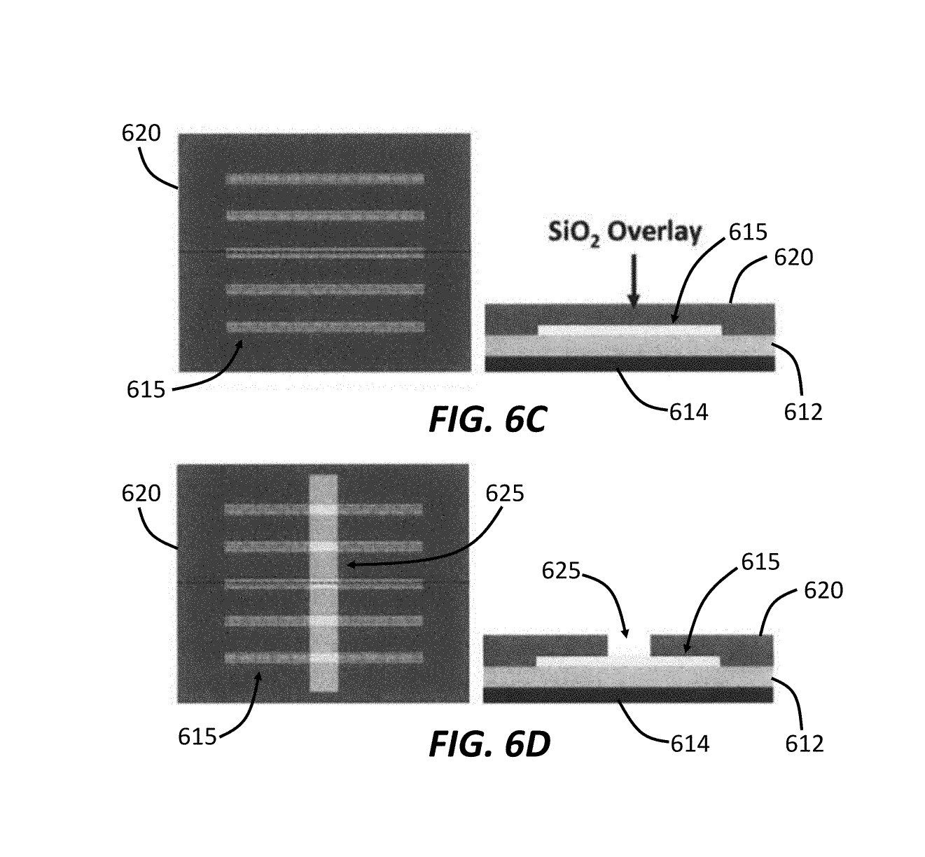

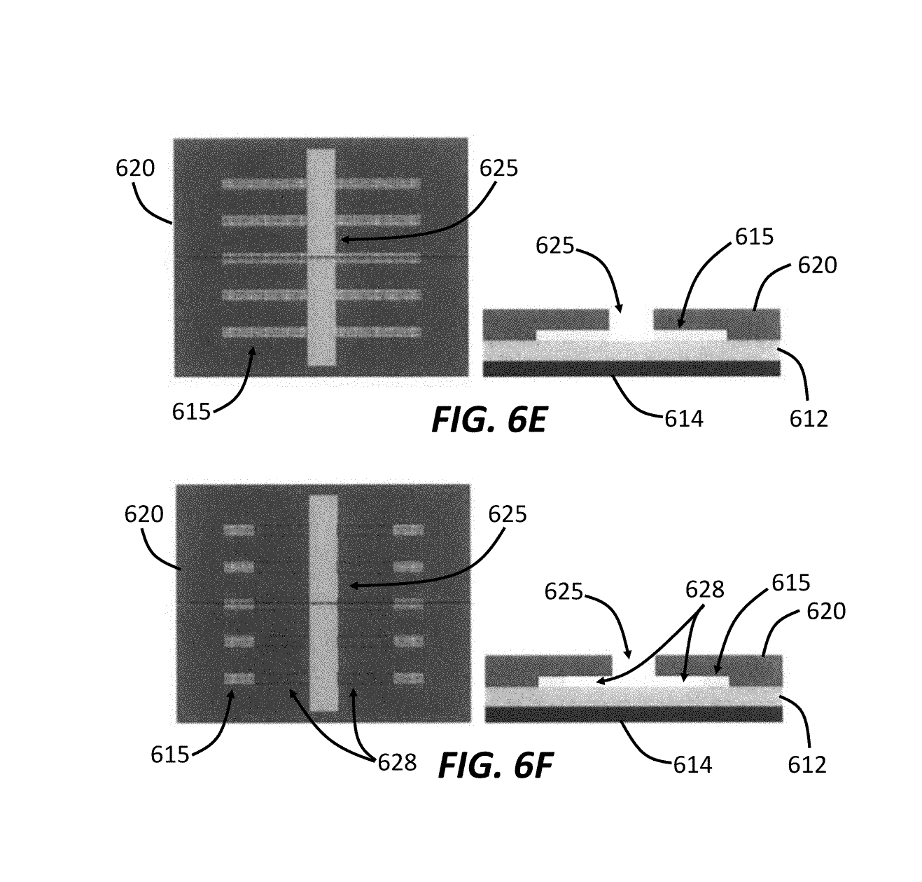

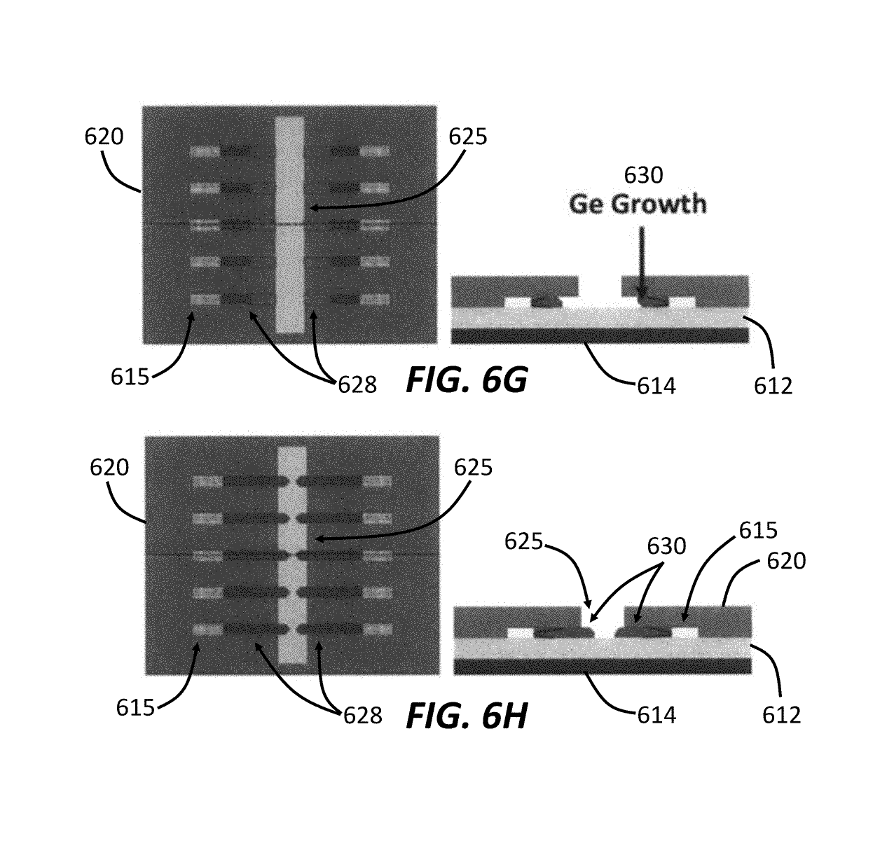

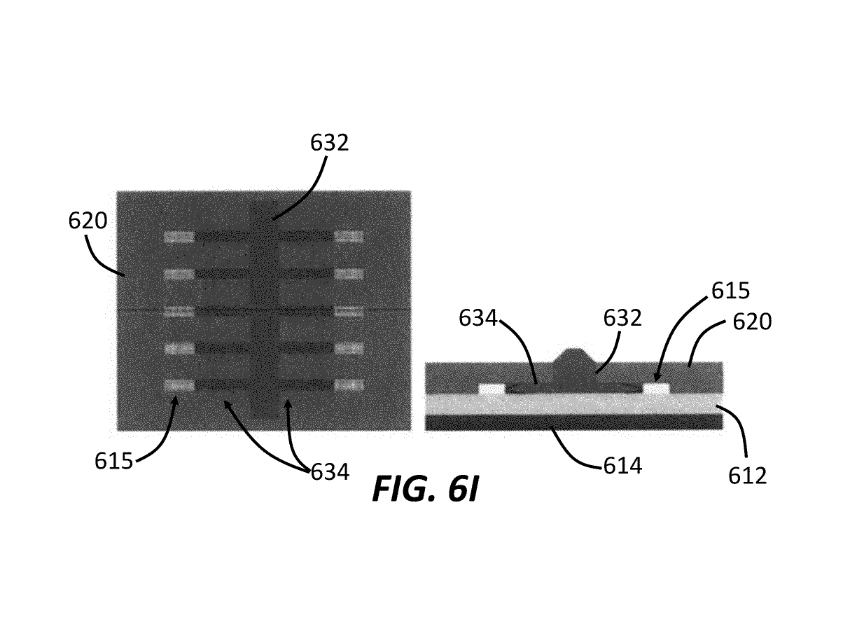

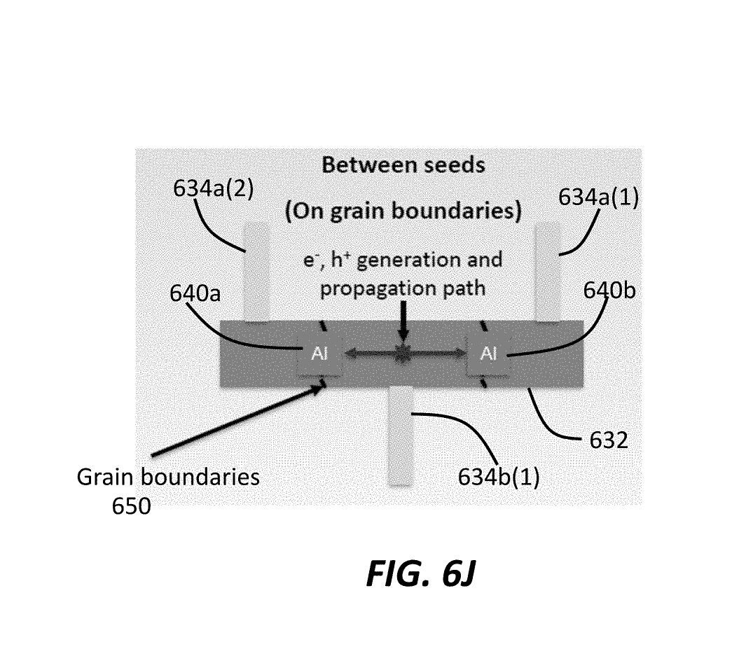

The dimensions of the side strips 120a and 120b are determined by the dimensions of the channels where Ge is initially grown (see more details below with reference to, e.g., FIGS. 3A-3C, and FIGS. 6A-6I). The dimensions of the channels, in turn, can affect the nucleation of Ge within the channels and the quality of crystalline Ge in the main strip 110. In some cases, the length of the side strips 120a and 120b can be about 200 nm to about 3 μm (e.g., about 200 nm, about 500 nm, about 1 μm, about 2 μm, or about 3 μm, including any values and sub ranges in between). In one example, the side strips 120a and 120b have the same length. In this case, a grain boundary can appear in the middle of the main strip 110 along the length of the main strip 110 (i.e., y direction in FIG. 1B). Alternatively, the first side strips 120a and the second side strips 120b can have different lengths. In this case, a grain boundary may appear away from the middle line of the main strip 110.

The width of the side strips 120a and 120b (i.e., the dimension along they direction) can be about 50 nm to about 500 nm (e.g., about 50 nm, about 100 nm, about 150 nm, about 200 nm, about 250 nm, about 300 nm, about 350 nm, about 400 nm, about 450 nm, or about 500 nm, including any values and sub ranges in between). The aspect ratio of the side strips 120a and 120b can be defined as the ratio of the length to the width. In some cases, the aspect ratio of the sides strips 120a and 120b can be about 1.2 to about 3.0 (e.g., about 1.2, about 1.4, about 1.6, about 1.8, about 2.0, about 2.2, about 2.4, about 2.6, about 2.8, or about 3.0, including any values and sub ranges in between).

The height of the side strips 120a and 120b (i.e., the dimension along the z direction) is less than the height of the main strip 110, because the side strips 120a and 120b are confined in the channels within the overlay SiO₂ layer 150. In some cases, the height of the side strips 120a and 120b can be about 30 nm to about 100 nm (e.g., about 30 nm, about 40 nm, about 50 nm, about 60 nm, about 70 nm, about 80 nm, about 90 nm, or about 100 nm, including any values and sub ranges in between).

In one example, the side strips 120a and 120b are disposed into a periodic array with a period or pitch of about 200 nm to about 2 μm (e.g., about 200 nm, about 400 nm, about 600 nm, about 800 nm, about 1 μm, about 1.2 μm, about 1.4 μm, about 1.6 μm, about 1.8 μm, or about 2 μm, including any values and sub ranges in between). In another example, the side strip 120a and 120b can include more than one pitch. For example, some of the side strips 120a and 120b can be arrayed at a first pitch and other side strips 120a and 120b can be arrayed at a second pitch different from the first pitch.

The growth seeds 130a and 130b are disposed at the end of the side strips 120a and 120b. The heights and widths of the growth seeds 130a and 130b are typically the same as the heights and widths of the corresponding side strips 120a and 120b. The lengths of the growth seeds 130a and 130b can be about 20 nm to about 100 nm (e.g., about 20 nm, about 40 nm, about 60 nm, about 80 nm, or about 100 nm, including any values and sub ranges in between).

In FIGS. 1A and 1B, amorphous silicon is used as the growth seeds 130. Alternatively, any other material that is CMOS compatible and allows growth of Ge can be used. For example, the growth seeds 130 can include amorphous Ge.

The electrodes 140 can include various types of materials, such as aluminum (Al), gold (Au), silver (Ag), titanium (Ti), or any other appropriate material. FIG. 1B shows two electrodes 140a and 140b for illustrative purposes. In practice, multiple electrodes can be disposed on the main strip 110 to form multiple photodetector units on the same substrate. The electrodes can be disposed into a periodic array along the length of the main strip 110. The electrode array can have a pitch of about 0.1 μm to about 5 μm (e.g., about 0.1 μm, about 0.2 μm, about 0.3 μm, about 0.5 μm, about 1 μm, about 1.5 μm, about 2 μm, about 3 μm, about 4 μm, or about 5 μm, including any values and sub ranges in between).

As shown in FIG. 1B, the main strip 110 extends along they direction and the side strips 120a and 120b extend along the x direction perpendicular to they direction. Alternatively, the direction of the main strip 110 can be oblique with respect to the direction of the side strips 120a and 120b. For example, the main strip 110 and the side strips 120a and 120b can define an angle of about 10 degrees to about 90 degrees (e.g., about 10 degrees, about 20 degrees, about 30 degrees, about 40 degrees, about 50 degrees, about 60 degrees, about 70 degrees, about 80 degrees, or about 90 degrees, including any values and sub ranges in between).

In FIGS. 1A and 1B, the first array of side strips 120a is aligned with the second array of side strips 120b, i.e., each side strip 120a from the first array is opposite a corresponding side strip 120b from the second array on the other side of the main strip 110. This aligned configuration allows a faster growth speed since Ge emerging from opposing channels can coalesce in the middle of the width of the main strip 110. On the other hand, coalescing in the middle of the width can also introduce a longitudinal grain boundary as illustrated in FIG. 1B. This longitudinal grain boundary can be eliminated using a staggered configuration of the side strips (and the growth seeds).

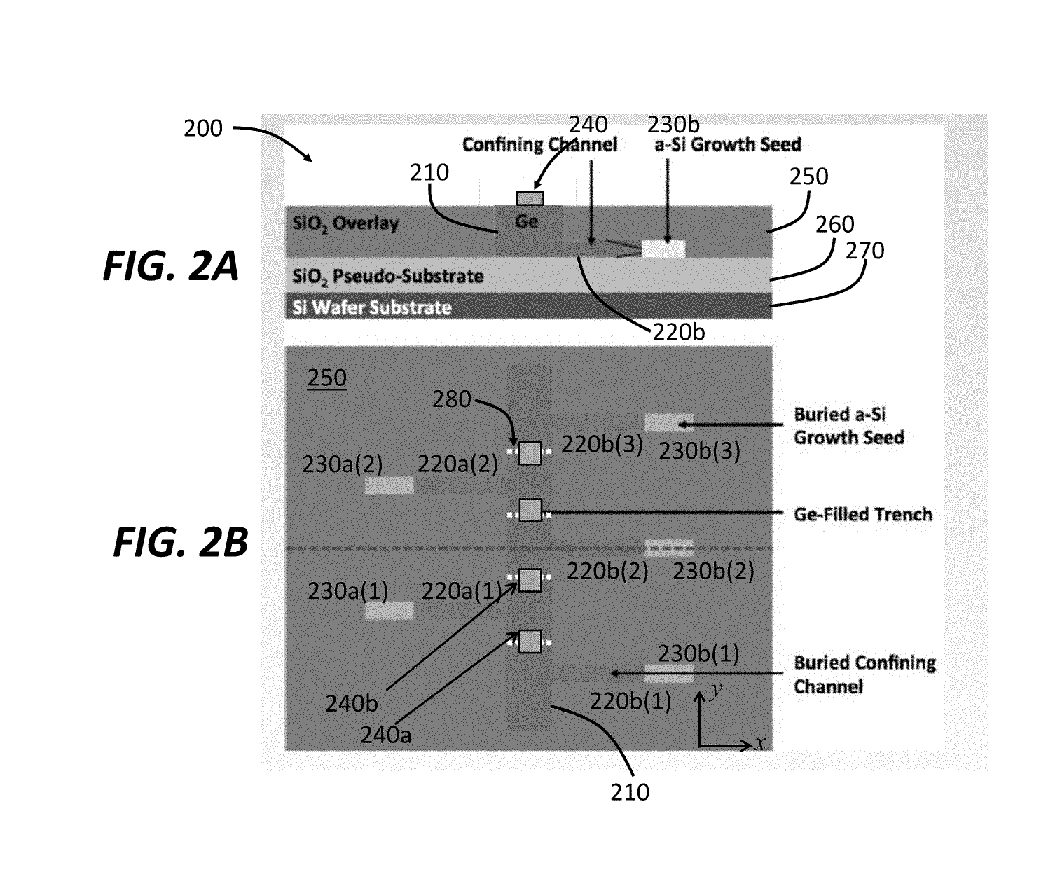

FIGS. 2A and 2B show a side view and a top view, respectively, of a germanium detector 200 including staggered arrays of amorphous silicon seeds. The detector 200 includes a main strip 210 disposed in a SiO₂ overlay layer 250, which is disposed on an amorphous substrate 260 and a Si wafer 270. A first array of side strips 220a (including 220a(1) and 220a(2)) is disposed on one side of the main strip 210 and a second array of side strips 220b (including 220b(1), 220b(2), and 220b(3)) is disposed on the other side of the main strip 210. Each side strip 220a/b(j) has a corresponding growth seed 230a/b(j). Multiple electrodes 240 (including 240a and 240b) are disposed on the main strip 210 to form an array of MSM photodetectors.

In FIGS. 2A and 2B, the first array of side strips 220a is staggered with respect to the second array of side strips 220b, such that Ge emerging from a given side strip first fills up the width of the trench where the main strip 210 is disposed (i.e., along the x direction) and then grows longitudinally along they direction to coalesce with Ge emerging from adjacent channels. In this case, the main strip 210 includes grain boundaries 280 extending along the x direction and these grain boundaries 280 can form a sequence along they direction in the main strip 210. Compared to the detector 100 in FIGS. 1A and 1B, the detector 200 has fewer grain boundaries and therefore a higher overall optical quality.

Two-Dimensional Geometrically Confined Lateral Growth

As described above, the photodetectors 100 and 200 can be fabricated via a two-dimensional geometrically confined lateral growth (2D GCLG) technique that is compatible with the temperature and substrate constraints in BEOL processing. 2D GCLG takes advantage of selective deposition, grain growth velocity anisotropy, and twinning to deposit single crystal Ge on an amorphous substrate.

FIGS. 3A-3C illustrate a method 300 of growing crystalline Ge via 2D GCLG. The method 300 can be used to form the side strips 130a and 130b (in FIGS. 1A and 1B) and 230a and 230b (in FIGS. 2A and 2B), as well as part of the main strips 110 (FIGS. 1A and 1B) and 210 (FIGS. 2A and 2B). In this method 300, a silicon substrate is oxidized in order to create an oxide pseudo-substrate 310, which is the amorphous substrate that the subsequent Ge deposition occurs on. A thin amorphous silicon (a-Si) film is deposited on the pseudo-substrate 310. The film thickness can be, for example, around 50 nm. The a-Si is patterned into a thin line 320 (e.g., about 100 nm to about 300 nm in width). A SiO₂ overlay layer 330 is disposed on the a-Si thin line 320 and substantially enclose the a-Si thin line 320 via plasma-enhanced chemical vapor deposition (PECVD). The SiO₂ overlay layer 330 can have a thickness of, for example, about 100 nm to about 5 μm (about 100 nm, about 200 nm, about 500 nm, about 1 μm, about 2 μm, about 3 μm, about 4 μm, or about 5 μm, including any values and sub ranges in between). Reactive ion etching (RIE) is performed to etch a window through the oxide overlay 330 to the oxide pseudo-substrate 310, thereby exposing the a-Si line 320. At this point, the thin a-Si line 320 is embedded in the overlay layer 330 with one end exposed to the air for subsequent processing. The resulting material system up to this step is shown in FIG. 3A.

FIG. 3B shows that the a-Si thin line 320 is selectively etched away to form a channel 325 within the SiO₂ overlay layer 330. The selective etching can be realized via, for example, the tetra-methyl-ammonium hydroxide (TMAH) process, which undercuts a-Si but not the surrounding SiO_{2.} The resulting channel 325 can have a large aspect ratio depending on the geometry of the a-Si line 320, which is under good control in the deposition process. The channel 325 has SiO₂ walls and a-Si 320 at the end to function as a seed for Ge growth.

FIG. 3C illustrates that Ge is grown from the a-Si seed 320 and extends along the channel 325 to form a Ge strip 340. Continuous growth of Ge beyond the Ge strip 340 can lead to a crystalline Ge grain 345. The growth can take place within an ultrahigh vacuum chemical vapor deposition reactor (UHVCVD) at about 450° C. The process is completely CMOS compatible; all processing takes place at or below 450° C. so that the process can be implemented in BEOL integration. During the Ge growth in the UHVCVD, the Ge selectively deposits on the a-Si, and not on the oxide (e.g., not on the pseudo-substrate 310 or the overlay layer 330).

Therefore, polycrystalline Ge deposition initiates on the a-Si seed 320 at the back of the oxide channel 325. With appropriate oxide channel geometry (see details below), by the time the Ge emerges from the channel 325, a single grain 345 of crystalline Ge emerges. The grain 345 can function as a seed for epitaxial growth of more Ge.

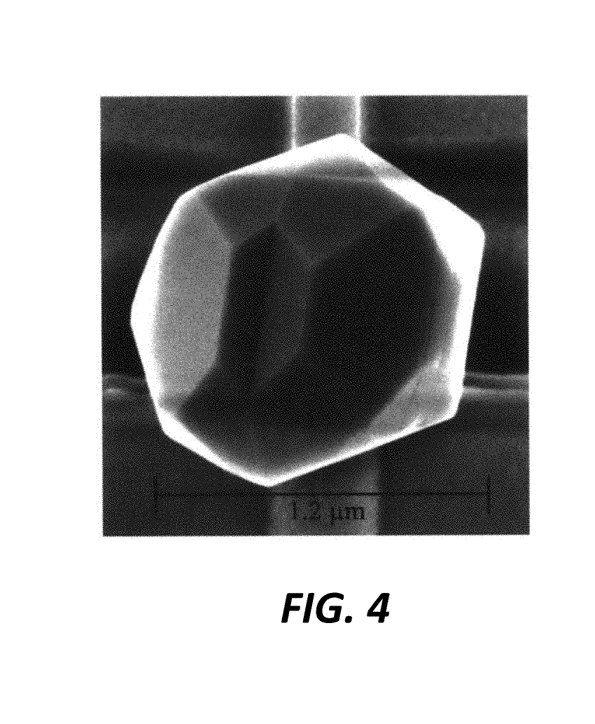

FIG. 4 is a plain-view scanning electron microscopy (SEM) image of Ge grown by the 2D GCLG method 300 illustrated in FIGS. 3A-3C. The bright vertical line below the Ge growth is the confining channel from which the Ge emerged. The large facets indicate that the Ge growth is crystalline. More details on 2D GCLG techniques can be found in U.S. Patent Application Publication No. 2016/0024687 A1, entitled “Confined Lateral Growth of Crystalline Germanium Material,” which is hereby incorporated herein by reference in its entirety.

In the method 300, the quality of the Ge 345 emerging out of the channel depends on the geometry of the channel 325. To fabricate Ge devices, such as detectors, it is usually desirable to have Ge in single crystalline form. Accordingly, it is also desirable to have a single crystalline grain emerging out of the channel 325 in the method 300 so as to grow more single crystalline Ge. The number of grains that can emerge out of the channel 325 depends on the geometry of the channel 325. Without being bound by any particular theory or mode of operation, the total number of grains N_{G} expected to emerge from a given channel is given by:

$${N}_{G} = ( \frac{12}{π {A}_{G}} ) {h}^{2} arcsin ( \frac{{h}^{2}}{4 {d}^{2} + {h}^{2}} ) \qquad ( 10$$

where A_{G} is the average base area of a Ge grain nucleated on a-Si at 450° C., h is the height of the channel, and d is the depth (i.e., length) of the channel.

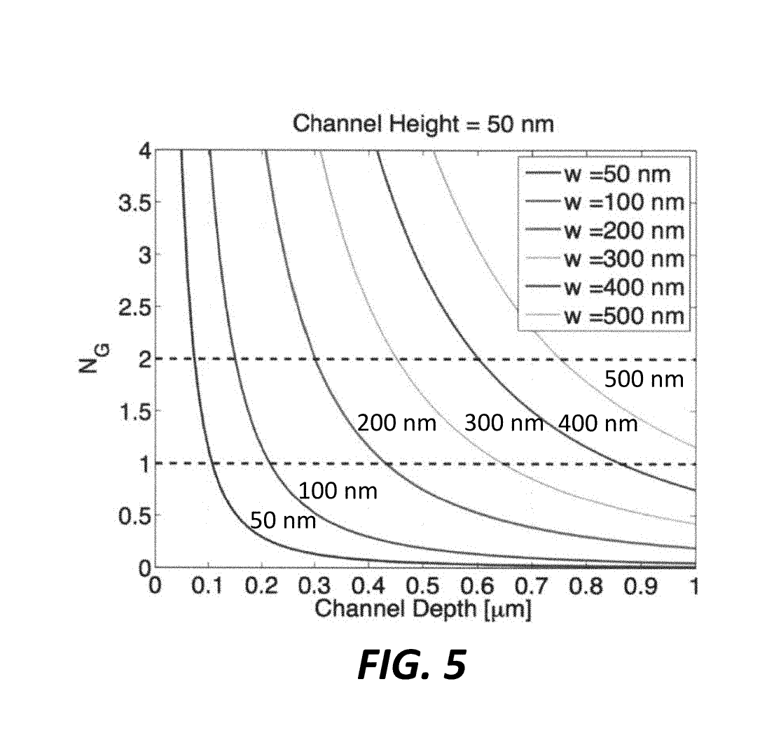

FIG. 5 shows the number of grains emerging out of a channel (e.g., channel 325 in FIG. 3B) as a function of the channel dimensions, calculated from Equation (1). In the plot, the height of the channel is held constant at 50 nm. The width of the channel increases from about 50 nm to about 500 nm. The width as used in each curve is marked on the right side of the corresponding curve. For example, the leftmost curve represents a channel width of about 50 nm and the rightmost curve represents a channel width of about 500 nm. Each curve is plotted as a function of the channel depth from 0 to about 1 μm.

Two dotted lines are drawn in FIG. 5, with one at N_{G}=1 and the other at N_{G}=2. These can be considered as the upper and lower bounds for practical fabrication. If N_{G}<1, then it can be expected that a Ge grain will not emerge from the channel every time. For example, if N_{G}=0.5, then a Ge grain may only emerge from 50% of the channels with this given geometry. If N_{G}=2, then it can be expected that two Ge grains can emerge from each channel. In practice, it can desirable for just one Ge grain to emerge from a given channel, i.e., N_{G} is between 1 and 2. Accordingly, one desired dimension window can be found in the region defined by the two dotted lines in FIG. 5.

Each individual curve in FIG. 5 shows that N_{G} decreases as the channel depth increases. Without being bound by any particularly theory, this is likely because as a channel gets deeper (i.e. longer), the aspect ratio gets larger, meaning that the solid angle of the opening decreases. Therefore, the likelihood of a randomly nucleated grain being oriented such that the (110) direction is pointing towards the channel opening decreases.

A second observation is that N_{G} increases as the height of the channel h increases. Without being bound by any particularly theory, one explanation of this phenomenon follows the same logic as before. A larger height can yield a larger channel opening and hence a larger solid angle of the channel opening. The larger solid angle in turn can lead to an increased probability that a randomly nucleated grain is oriented such that its (110) direction intercepts the channel opening.

The geometry of the channel, in some cases, can be constrained by incorporation of hydrogen into the a-Si film (e.g., the film fabricated into the a-Si line 320). The channel height is determined by the a-Si film thickness, which is deposited by plasma-enhanced chemical vapor deposition (PECVD). Amorphous Si deposited by PECVD is typically subjected to hydrogen incorporation into the Si during deposition. For example, the hydrogen concentrations can be approximately 10 at. %, depending on the deposition conditions. At concentrations greater than 10 at. %, micro-cavities can form with H selectively segregating to these cavities. When heated to 450° C., the hydrogen that is trapped within the film can become mobile, leading to hydrogen coalescence and the formation of bubbles. The hydrogen bubbles can eventually burst, thereby damaging the planar Si film. Therefore, it can be helpful to keep the a-Si film below a certain value so as to reduce the amount of hydrogen trapped within the film. For example, the thickness of the a-Si film (and accordingly the height of the channel) can be substantially equal to or less than 100 nm (e.g., about 100 nm, about 90 nm, about 80 nm, about 70 nm, about 60 nm, about 50 nm, about 40 nm, about 30 nm, or less, including any values and sub ranges in between). In some cases, the fabrication facility may overcome the incorporation of hydrogen into the a-Si film. Accordingly, the a-Si film can have a larger thickness (e.g., greater than 100 nm).

Once the channel height is fixed, the channel width and depth can be chosen based on the plots in FIG. 5. For example, with a 50 nm channel height, a channel width of about 50 nm and a channel depth of about 100 nm can be used to achieve an N_{G} between 1 and 2. In another example, for channel widths of 100 nm, 200 nm, and 300 nm, channel depths of 175 nm, 350 nm, and 550 nm can be used, respectively.

Fabricating an Active Region in a Ge Device

Ge devices usually have an active region with a width of about 500 nm, a height of about 200 nm to about 500 nm, and a length of about tens of microns. These dimensions are typical for waveguide integrated Ge optoelectronic devices, such as photodetectors and electro-absorption modulators. For example, the cross section of approximately 500 nm by 500 nm can be useful in forming a single-mode Ge waveguide for light at a wavelength of about 1.55 μm widely used in telecommunication. To fabricate these active regions, the 2D GCLG technique can be used to fill a trench (or other shapes of void space) having dimensions similar to those of the active regions.

In one example, a single channel (e.g., the channel 325) can be used to grow a Ge strip used as an active region in Ge devices. In this case, the channel can be connected to a trench perpendicular to the channel. Once Ge emerges out of the channel, the growth can continue along the extension of the trench so as to fill the trench. This approach is straightforward but can be time consuming.

Alternatively, multiple 2D GCLG channels can be used to seed multiple Ge crystallites and the final Ge strip can be coalesced by Ge contributed from a combination of these channels. In this configuration, multiple 2D GCLG channels are arrayed with openings into a common trench. Multiple Ge crystallites nucleate within the trench, and then grow epitaxially until the crystallites coalesce and eventually fill the trench.

Ge growth using multiple channels via 2D GCLG technique is very different from conventional fabrication techniques. Typically, Ge optoelectronic devices are fabricated in a planar fashion. For example, a planar film is deposited and then etched into the appropriate device geometry. Alternatively, a trench is etched in SiO₂ and Ge is selectively deposited on a Si substrate. In both conventional techniques, the growth time is determined by the desired film thickness.

In contrast, in the approach with multiple channels in 2D GCLG, the growth time depends on the distance between the channels (or the pitch of the channel array) and the depth of the trench (i.e., the height of the resulting Ge strip). In other words, the Ge fabrication described herein includes three phases: Ge growth within the channel until Ge emerges from the channel, vertical growth of Ge to fill the trench, and lateral growth of Ge to coalesce with Ge from the neighboring channels. Each phase can contribute to the total time duration for the fabrication of Ge devices. In some cases (e.g., when the distance between channels is greater than the height of the trench), vertical growth can be simultaneous with the lateral growth. In these cases, once the grain emerges from the channel, the vertical growth occurs simultaneously with the lateral growth (until coalescence). Accordingly, the fabrication can include only two phases: Ge growth within the channel, and growth within the trench until coalescence.

Multiple channels can be arranged in at least two configurations. In one example, as shown in FIGS. 1A and 1B, the channels on opposite sides of the trench are aligned with each other. In another example, as shown in FIGS. 2A and 2B, the channels on opposite sides of the trench are staggered. Both approaches utilize an array of 2D GCLG channels to nucleate Ge crystallites within the trench, and then grow epitaxially until the crystallites coalesce and fill the trench.

The approach with aligned seeds (e.g., FIGS. 1A and 1B) can reduce Ge growth time and simplify the fabrication process. The growth time is reduced because the channels (and accordingly the Ge emerging out of the channels) are closer to each other and therefore it takes the Ge grains less growth distance before they coalesce. It is also easier to fabricate Ge strips in this approach because the lithography step that defines the channels (see, e.g., FIG. 6B below) can be performed with less restraints on the precision of the aligning mask.

The staggered channel approach, on the other hand, can reduce the number of grains in the trench, and therefore improve the overall crystal quality of the Ge material within the trench. Compared with the aligned channel approach, the staggered channel approach usually uses only half the number of channels during growth. Typically, a single grain emerges from each channel. Therefore, using half the number of channels can lead to 50% fewer grains in the resulting Ge strip (e.g., Ge strips 210) and accordingly 50% fewer grain boundaries. Grain boundaries can act as carrier recombination sites, optical scattering sites, and electrical scattering sites, and create high resistance and current blocking barriers. Therefore, fewer grain boundaries are beneficial for higher device quality.

In both approaches, the exact number of grains, their physical location, and their size, can be controlled by the number of channels and the spacing between them. In general, a larger channel pitch (period) can lead to larger Ge grains at coalescence, thereby enhancing the overall crystal quality of the resulting Ge strip. But a larger channel pitch can also increase the time for the Ge grains to meet each other and coalesce. The increase of growth time can be aggravated at low temperatures. For example, depending on germane overpressure, growth times can be between about 18 hours to about 20 hour to grow approximately 1.5 μm of Ge, yielding a growth rate of approximately 75 nm per hour. Therefore, in practical fabrication, there is a trade-off between ease of fabrication, crystal quality, and Ge growth time.

FIGS. 6A-6I illustrate a method 600 of fabricating active regions in Ge photodetectors. In each figure, the left side shows a top view of the resulting device and the right side shows a cross sectional view of the device through the dotted line shown in the left figure. All steps in the method 600 are CMOS compatible and can be carried out at or below 450° C.

The method 600 includes forming a pseudo-substrate 612 on a Si wafer 614. For example, the pseudo-substrate 612 can include a SiO₂ layer deposited on the Si wafer 614 using a plasma-enhanced CVD (PECVD) deposition technique. The pseudo-substrate 612 can provide mechanical support for other components in subsequent processing, but the Ge is not epitaxially grown from this pseudo-substrate 612. In some cases, it can be desirable to use a material that does not support epitaxial growth of Ge so as to selectively grow Ge only from the selected seed (see, e.g., FIG. 6G below). The pseudo-substrate 612 can also emulate the amorphous dielectric in the back end of the interconnect stack in a CMOS process flow.

A thin layer of a-Si 610 is deposited on the oxide pseudo-substrate 612 using, for example, PECVD, as shown in FIG. 6A. The thickness of the a-Si layer 610 determines the height of the 2D GCLG channel. As described above, considering the potential issues with hydrogen trapping, the thickness of the a-Si layer can be substantially equal to or less than 100 nm (e.g., about 100 nm, about 90 nm, about 80 nm, about 70 nm, about 60 nm, about 50 nm, about 40 nm, about 30 nm, or less, including any values and sub ranges in between). In some cases, the thickness of the a-Si layer can be greater than 100 nm once the hydrogen trapping is overcome.

FIG. 6B shows that the a-Si layer 610 is patterned into an array of a-Si strips 615 (also referred to as a-Si thin lines 615) via lithography. The width of each a-Si strip 615 determines the width of the 2D GCLG channels. In some cases, the width of the a-Si strip 615 can be about 100 nm to about 300 nm (e.g., about 100 nm, about 150 nm, about 200 nm, about 250 nm, or about 300 nm, including any values and sub ranges in between). The pitch of the a-Si strips 615 can be about 200 nm to about 2 μm (e.g., about 200 nm, about 400 nm, about 600 nm, about 800 nm, about 1 μm, about 1.2 μm, about 1.4 μm, about 1.6 μm, about 1.8 μm, or about 2 μm, including any values and sub ranges in between).

Any dimensions described herein in this application are for illustrative purposes only. Different types of lithography (e.g., immersion, EUV, or electron beam lithography) and different patterning approaches (e.g., self-aligned double patterning, or self-aligned quadruple patterning) can make much smaller features with much smaller pitches. In practice, smaller a-Si widths (e.g., less than 100 nm) and smaller seed pitches (e.g., less than 200 nm) can be beneficial as they can lead to shorter growth times. Advanced lithography techniques can produce features as small as 10 nm with a pitch of 20 nm.

In lithography, the stepper that is used to pattern the a-Si strips 615 can have a reliable resolution limit of about 1 μm. In this case, a double exposure technique with a sub-micron offset can be employed to fabricate a-Si strips 615 with widths less than 1 μm. For example, after double exposure of the photoresist, the remaining photoresist lines can be further thinned by dry etching in an oxygen plasma. With this approach, a-Si strips 615 that are about 100 nm wide can be fabricated with a stepper that is otherwise only capable of exposing 1 μm features.

FIG. 6C shows that an overlay layer 620 is deposited on the a-Si strips 615 and substantially enclose the a-Si strips 615 within the overlay layer 620. The deposition can be carried out using PECVD. The overlay layer 620 can include, for example, SiO₂ or other materials that do not seed epitaxial growth of Ge. The thickness of the overlay layer 620 determines the height of the trench that is to be filled to form the Ge strip. In some cases, the thickness of the overlay layer 620 can be about 200 nm to about 500 nm (e.g., about 200 nm, about 250 nm, about 300 nm, about 350 nm, about 400 nm, about 450 nm, or about 500 nm, including any values and ranges in between).

FIG. 6D shows that a trench 625 is opened up in the overlay layer 620. At this step, RIE dry etching can be used to etch the overlay layer 620 and expose the a-Si strips 615 underneath the overlay layer 620. FIG. 6E shows that the a-Si strip 615 is dry etched and the trench 625 extends vertically to the pseudo-substrate 612. At this point, the a-Si strips 615 intersect the side walls of the trench 625.

FIG. 6F shows that an undercut etching of the a-Si strips 615 is performed to form channels 628 sandwiched between the overlay layer 620 and the pseudo-substrate 612. The undercut can be realized via, for example, a tetramethylammonium hydroxide (TMAH) wet etch at about 80° C. TMAH selectively etches Si but not SiO₂, thereby creating channels 628 while leaving intact the overlay layer 620 and the pseudo-substrate 612. After the TMAH wet etching, the remaining a-Si strips 615 are disposed at the ends of the channels 628 and can function as growth seeds for subsequent growth of Ge. The amount of TMAH wet etch determines the depth (i.e., length) of the channels 628. As described above, the depth of the channels 628 can affect the number of Ge grains emerging out of the channels 628. In practice, the depth of the channels 628 can be determined using FIG. 5 as guidance.

The structure shown in FIG. 6F can be used as a platform to fabricate active regions for Ge devices by filling the trench 625 with crystalline Ge. Before Ge growth, the structure shown in FIG. 6F can be cleaned with a standard RCA clean, ending with a quick dip in hydrofluoric acid (HF). This step can passivate the exposed Si by occupying the dangling bonds in Si with H, thereby inhibiting the formation of a native oxide.

The cleaned structure can be loaded into an ultra-high vacuum chemical vapor deposition (UHVCVD) reactor. The a-Si strips 615, the overlay layer 620,and the pseudo-substrate 612 deposited by PECVD usually have some hydrogen incorporated into the films. To remove the hydrogen, the structure can be annealed in the UHVCVD reactor. In one example, the annealing condition can include a base pressure of about 1.8×10⁻⁸ mbar and an annealing duration of about two hours to sufficiently out-gas the hydrogen from the films.

FIG. 6G shows a Ge growth step starting from the a-Si strips 615 and extending along the channels 628 toward the trench 625. The growth can be carried out with a germane (GeH₄) flow at about 7.5 sccm. The chamber temperature can be about 450° C. and the growth pressure can be about 3.4×10⁻³ mbar. The growth can operate without carrier gases. At this step, Ge 630 selectively deposits on the a-Si strips 615, but not on the exposed pseudo-substrate 612. In other words, the pseudo-substrate 612 provides mechanical support to the Ge 630 but does not initiate growth of the Ge 630. In this manner, the crystalline quality of the Ge 630 can be controlled by the geometry of the channels 628 without interference from the underlying substrates (e.g., 612).

FIG. 6H shows that the Ge 630 emerges from the channels 628 as single-crystal crystallites. These crystallites are used to seed epitaxial growth of more Ge until the neighboring crystallites coalesce and eventually fill the trench 625, as shown in FIG. 6I. The filling of the trench 625 and the channels 628 results in a main strip 632 and two arrays of side strips 634. The main strip 632 and the side strips 634 are separately labelled in FIG. 6I, but in practice they are typically in a continuous Ge structure. Some Ge can grow out of the trench 625 to form a non-planar and faceted top surface on the main strip 632, as shown in the side view in FIG. 6I. A chemically and mechanically polishing (CMP) step can be performed to planarize the main strip 632 before fabricating Ge devices where low-loss modal propagation is desirable.

One significant benefit to the geometrically confined growth technique is that all grains locations are lithographically defined by the placement of the confinement channels 628 and nucleation seeds 615. Therefore, the location of the grain boundaries is known. FIG. 6J shows that grain boundaries 650 appears in the main strip 632 at locations between neighboring side strips 634a(1) and 634b(1), as well as between side strips 634a(2) and 634b(1). In one example, metal contacts 640a and 640b for photodetectors can be disposed within the area defined by the grain boundaries 650, i.e., within one grain on the crystalline Ge. In another example, the metal contacts 640a and 640b can be disposed on the grain boundaries 650. In yet another example, more than two metal contacts can be disposed within the area defined by the grain boundaries 650. A smaller distance between the metal contacts can, for example, increase the gain of the resulting detector. The distance between adjacent grain boundaries 650 can be about 100 nm to about 2 μm (e.g., about 100 nm, about 200 nm, about 300 nm, about 500 nm, about 1 μm, or about 2 μm, including any values and sub ranges in between).

The metal contacts 640a and 640b apply the electric field to the Ge, and therefore the electron hole pairs are generated between the contacts 640a and 640b and drift in separate directions towards the metal contacts 640a and 640b where they are collected. When the metal contacts 640a and 640b are placed on the grain boundaries 650, the carriers are generated in the crystalline material and do not have to cross a grain boundary before they are collected.

Therefore, from the perspective of the carriers, the device is single-crystalline, despite the presence of grain boundaries.

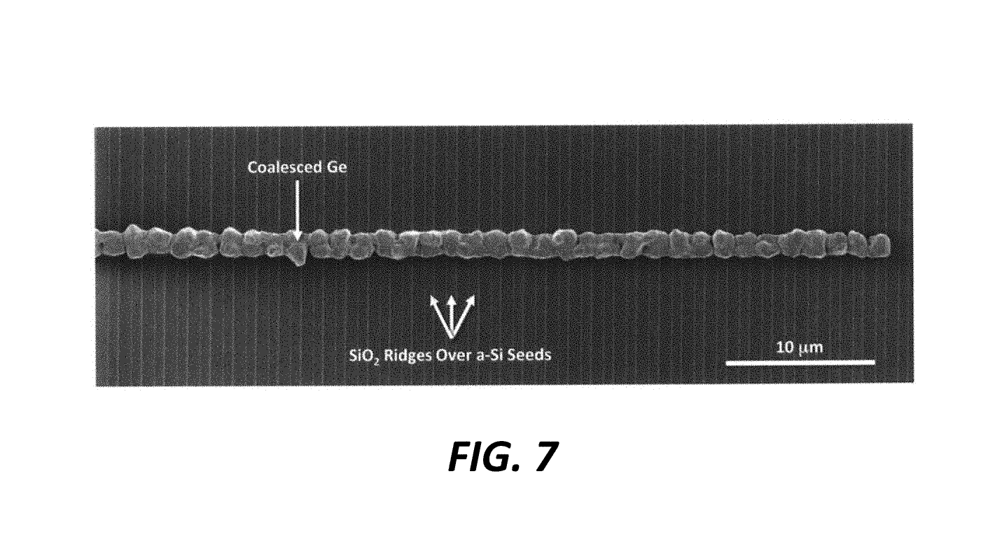

FIG. 7 shows a plan-view SEM image of a lithographically-defined trench filled with Ge grains that are grown using the method illustrated in FIGS. 6A-6I. The SEM image shows a trench that is greater than 50 μm long, and is completely filled with Ge. The vertical lines in the image are caused by the a-Si seed lines. The SiO₂ overlay deposition process is not planarized and therefore expands the shape of the a-Si seed lines. The vertical lines are SiO₂ and also indicate the location of the underneath growth seeds.

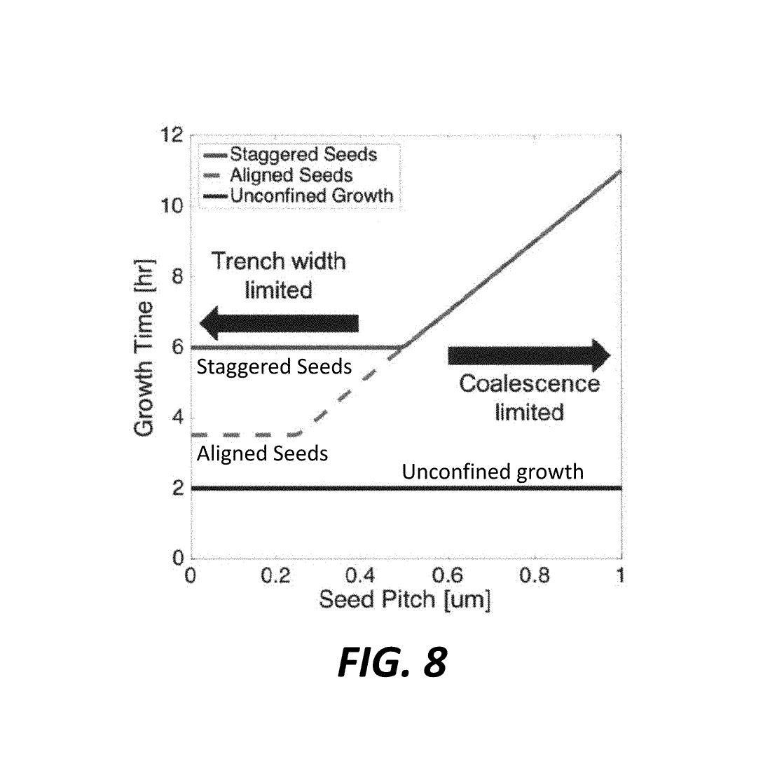

FIG. 8 shows calculated growth time as a function of the pitch of the growth channels. The growth time is calculated using a trench that is 500 nm wide by 200 nm deep. Three configurations are included in FIG. 8 for comparison. The unconfined growth configuration (standard planar growth from substrate) does not have a seed and is therefore a constant. The growth time is determined using a growth rate of about 100 nm h ⁻¹, as observed experimentally at 450° C. and a pressure of 1×10′ mbar. In the aligned seeds configuration, the two arrays of growth seeds (and the channels 628) are opposite each other across the trench. In the staggered seeds configuration, the two arrays of growth seeds are staggered with respect to each other (see, e.g., FIGS. 2A and 2B).

When the seed pitch is large, the seeds are far away from each other and the total growth time depends mostly on the time for the grains to grow laterally along the length of the trench and coalesce with the neighboring grains. When the pitch is very small, the total growth time becomes more sensitive to the time for the Ge to fill the width of the trench because the lateral growth distance along the trench for coalescence is small.

In the staggered seed configuration, each grain grows large enough to fill the entire width of the trench (e.g., 500 nm). In contrast, in the aligned seed configuration, the grain can only grow half the width of the trench before coalescing with the grain on the opposite side of the trench. Therefore, the aligned seed configuration allows for faster growth and higher manufacturing throughput, but at the expense of the addition of an additional grain boundary running down the middle of the trench. In practice, the configuration can be determined in consideration of the trade-off between throughput and material quality.

Fabrication of Ge Active Regions Using Silicon Nitride for Channel Formation

In the method 600 illustrated in FIGS. 6A-6I, the depth (or length) of the channels 628 is determined by the amount of TMAH etching (usually a timed etching) of the a-Si strips 615. Variation of the TMAH etching can be caused by, for example, mass-transport limitations due to the small cross-sectional dimensions of the channels. The variation of the TMAH, in turn, can introduce variations into the depth of the resulting channels 628. In the aligned seed configuration, Ge emerging out of channels having different depths may coalesce at different lateral locations in the trench, thereby forming a corrugated grain boundary. In addition, the variations in the channel depth may also affect the number of Ge grains emerging out of the channels as described above (see, e.g., FIG. 5).

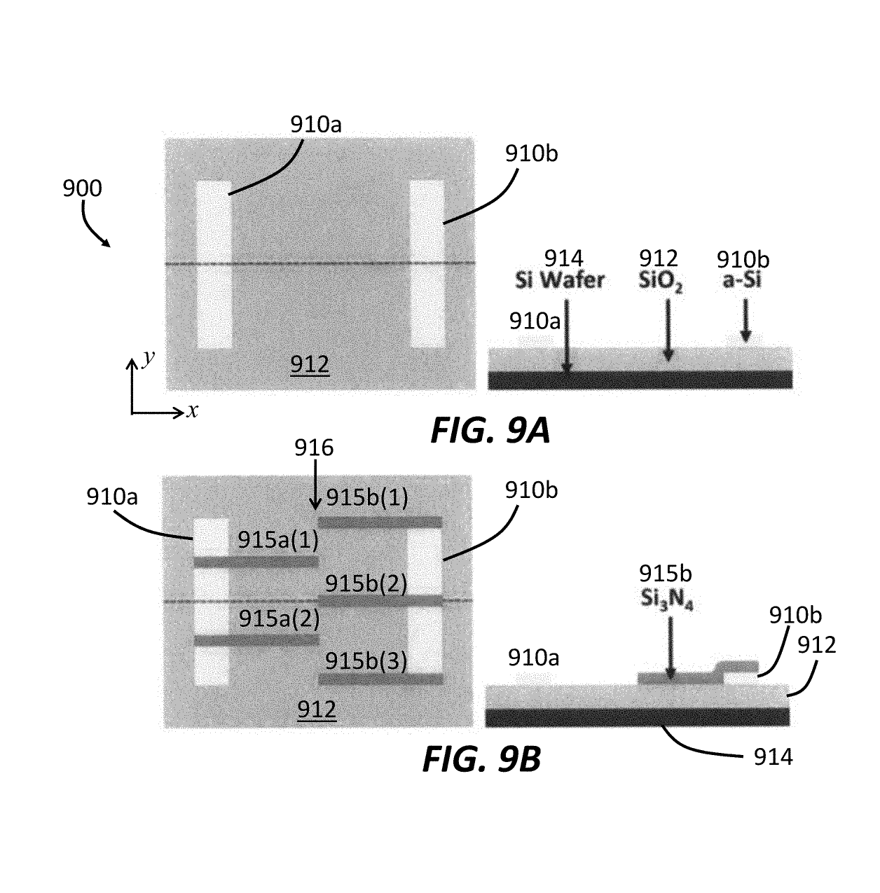

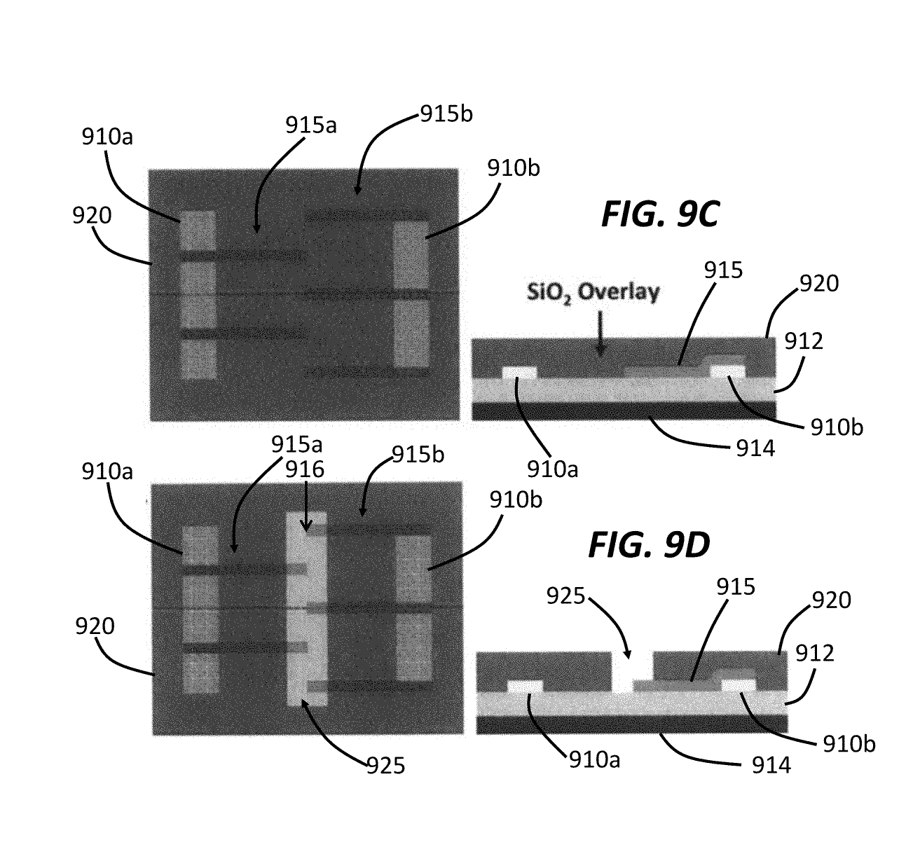

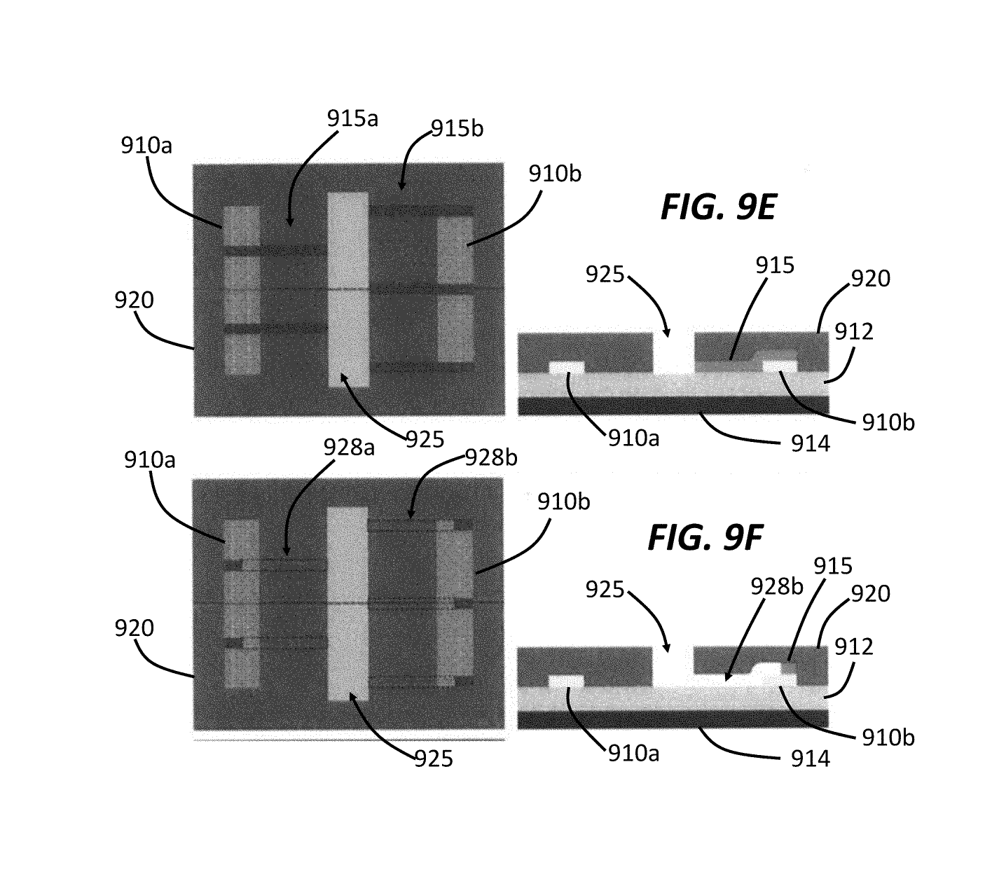

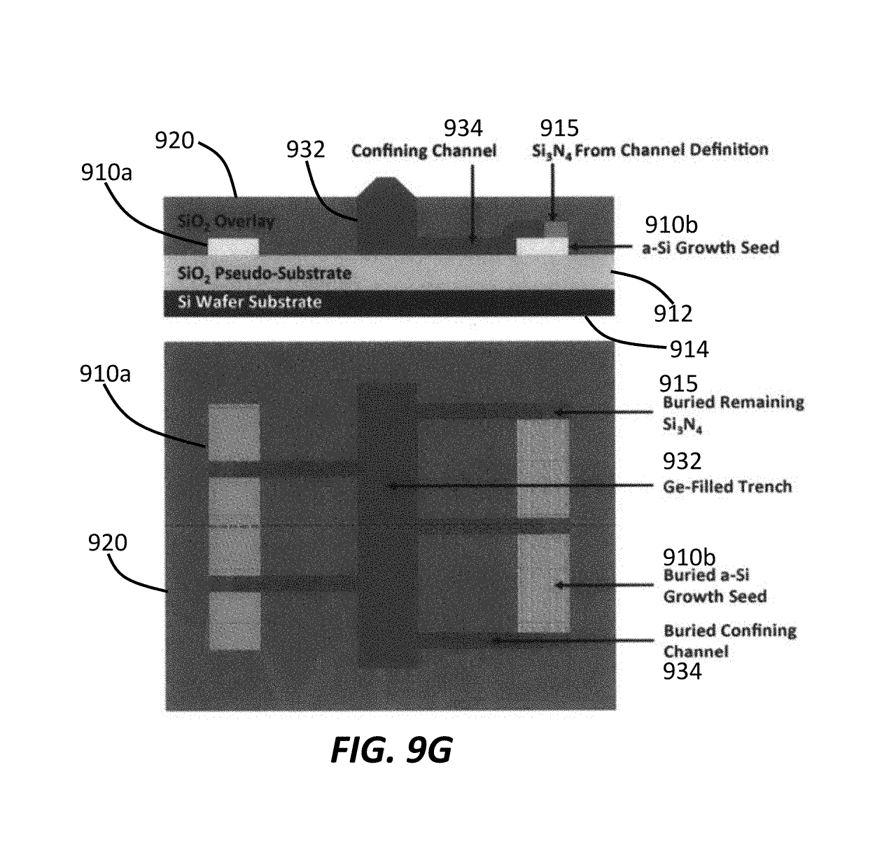

FIGS. 9A-9G illustrate a method 900 of fabricating Ge active regions using silicon nitride (e.g., Si₃N₄) for channel formation. In the method 900, the channels are formed by selectively etching Si₃N₄ strips disposed in contact with a-Si strips until the a-Si is exposed. In this manner, the a-Si can function as an etch stop. Over etching or under etching does not affect the resulting depth channel, which is defined by the set distance between the a-Si strips and the trench. In this method, channel dimensions are controlled with either lithography or film thicknesses. Film thicknesses can be carefully controlled, and are reliable and repeatable. With the right equipment, patterning with lithography can be very accurate and reproducible. Therefore, the yield of the nitride fabrication method 900 can be high due to reliable and reproducible trench filling.

The method 900 includes forming a pseudo-substrate 912 (e.g., SiO₂) on a silicon wafer 914 via, for example, PECVD. The pseudo-substrate 912 can emulate the wafer surface above the interconnect stack in a Si CMOS process flow. An a-Si film is deposited using PECVD on the pseudo-substrate 912. The thickness of the a-Si film can determine the height of the channels to be formed in subsequent steps (see, e.g., FIG. 9F). The a-Si film is then patterned into two parallel a-Si strips 910a and 910b (collectively referred to as the a-Si strip 910), as shown in FIG. 9A.

The length of the a-Si strips 910 (i.e., the dimension along they direction) can be approximately the same as the length of the trench to be formed (see, e.g., FIG. 9D). The distance between the a-Si strips 910 (the distance along the x direction) is substantially equal to two times the desired channel depth plus the width of the trench.

After the a-Si strips 910 are patterned, a Si₃N₄ film is deposited using PECVD to cover both the a-Si strips 910 and the exposed pseudo-substrate 912. The thickness of the Si₃N₄ film can be substantially equal to the thickness of the a-Si strips 910 (and accordingly the height of the 2D GCLG channel). The Si₃N₄ film is then patterned into a first array of Si₃N₄ strips 915a (including 915a(1) and 915a(2)) and a second array of Si₃N₄ strips 915b (including 915b(1), 915b(2), and 915b(3)). These Si₃N₄ strips 915a and 915b (collectively referred to as Si₃N₄ strips 915) are also referred to as nitride strips or nitride lines throughout this application. Each Si₃N₄ strip 915 includes one section that covers the pseudo-substrate 912 and another section that covers one of the a-Si strips 910a or 910b, as shown in FIG. 9B.

The width of the Si₃N₄ strips 915 is equal to the width of the of the growth channels. In FIG. 9B, the two arrays of Si₃N₄ strips 915a and 915b are patterned in a staggered configuration in order to increase the grain size. Deep ultraviolet (DUV) lithography can be used to achieve accurate alignment between mask levels. In one example, one edge 916 of the staggered nitride strips 915 can be aligned with the center of the trench. The other edge of the staggered nitride strips 915 can overlap the a-Si strips 910. This configuration can increase the tolerance to imprecision of mask alignment. In another example, the nitride strips 915 do not cover the a-Si strips 910. Instead, the nitride strips 915 extend until they reach the a-Si strips 910. This configuration can simply deposition and subsequent etching but may be more prone to misalignment of etching masks.

FIG. 9C shows that an overlay layer 920 is disposed on the a-Si strips 910, the nitride strips 915, and the pseudo-substrate 912. The overlay layer 920 can include SiO₂ and can be deposited via PECVD techniques. The thickness of the overlay layer 920 defines the height of the trench.

FIG. 9D shows that a trench 925 is patterned in the overlay layer 920. For example, the overlay layer 920 can include SiO₂ and can be selectively dry etched to form vertical sidewalls within the SiO_{2.} This dry etching step exposes the end 916 of the two arrays of nitride strips 915a and 915b for subsequent processing.

FIG. 9E shows that the exposed end 916 of the nitride strips 915 are dry etched, increasing the depth of the trench 925 until the pseudo-substrate 912. The remaining nitride strips 915 are then undercut etched to form channels 928a and 928b (collectively referred to as channels 928) until the a-Si strips 910 are exposed to the channels 928, as illustrated in FIG. 9F.

The undercut etch can be performed by a wet etch in hot phosphoric acid, which can selectively etch Si₃N₄ without etching the SiO₂ or the a-Si. Due to the etch selectivity, the Si₃N₄ strips 915 can be over-etched without damaging other components in the structure. This can reduce or eliminate the effect of variable undercut etch rates in TMAH. In this manner, the nitride strips 915 can define the channel cross-sectional dimensions. The total depth of the channels 928 is determined by the space between the a-Si strips 910 and the trench 925, which is defined lithographically and is not subject to any variations in the selective etching step.

FIG. 9G shows that Ge is deposited into the channels 928 and the trench 925 to form side strips 934 and a main strip 932, respectively. The deposition can be carried out in a UHVCVD reactor at about 450° C. The Ge can randomly nucleate on the a-Si seeds 910 at the end of the growth channels 928. With the appropriate channel design (e.g., channel depth and width, see FIG. 5), a single crystal Ge crystallite can emerge from each channel 928, and therefore seed epitaxial growth within the trench 925. The crystallites continue to grow epitaxially until the grains coalesce with the neighboring grains, effectively filling the trench and forming the main strip 932.

Ge Metal-Semiconductor-Metal (MSM) Photodetectors

The active regions (e.g., main strips 632 and 932) fabricated via the methods 600 and 900 described above can be used to form various Ge devices, such as photodetectors and modulators. For example, a strip of crystalline Ge and two electrodes can form a Ge metal-semiconductor-metal (MSM) photodetector. MSM photodetectors can operate without doping (i.e., without PN junctions) and therefore are easier to fabricate than photodiodes. In addition, MSM photodetectors are also compatible with BEOL processing, because doping usually involves an annealing step that occurs at high temperatures (e.g., higher than 700° C.).

Two types of electrodes can be used in Ge MSM photodetectors. In one example, the electrodes include Ohmic contacts, which can be formed by direct metallization of a metal material on the Ge strip. Direct sputtering can be used to form a metal layer onto a polished polycrystalline germanium film. The metal layer can be then patterned by depositing though a shadow mask to form individual metal contacts. The metal material can include, for example, Al, Co, Fe, Ni, Au, Ag, and Ti, among others. Alternatively, the metal patterning can be achieved by the sputtering of a blanket film, followed by conventional lithography for the patterning. A dry etch can be used to transfer the pattern into the metal contact.

In another example, the electrodes include Schottky contacts, which can be formed by disposing a dielectric interlayer between a metal material and the Ge strip. Schottky contacts can have a lower level of dark current than Ohmic contacts. Each Schottky contact can be regarded as a diode. Since a Ge MSM photodetector includes two electrodes and is symmetric, one contact can be in reverse bias and the other contact can be in forward bias. The total current through the photodetector can be limited (or rectified) by the reverse biased Schottky contact. Therefore, the dark current of the detector can be reduced.

Cleaning of Ge Surfaces

Before forming electrodes (either Ohmic or Schottky), the Ge strip can be cleaned to remove oxides or contaminants. Without any treatment, a Ge surface that is exposed to ambient conditions usually forms a native oxide. This oxidized surface can be contaminated by the adventitious adsorption of water vapor, hydrocarbons, and carbon. Since the contamination arises from an uncontrolled process, the contaminants can be spatially non-uniform and inconsistent from wafer to wafer. Therefore, it can be helpful to clean the surface of the Ge and form a pristine interface between the Ge and the electrodes.

In addition to removing the native oxide and contaminants, a chemical treatment can also alter the electronic properties of the surface. For example, exposing a Ge surface to HF can passify the dangling bonds of the surface Ge atoms and significantly reduce the surface recombination velocity.

Various methods can be used to clean and/or treat the Ge surface. In one example, the Ge can be treated via a plasma etch-back process. This process can use argon ion bombardment in the plasma state to mechanically remove the native oxide from the surface of the Ge. The treatment can be performed inside a sputtering chamber and immediately before metal deposition. The power in this step can be kept low (e.g., substantially equal to or less than 25 W) in order to reduce the probability of structural damage to the Ge surface.

In another example, the Ge surface can be treated using an HF process to chemically remove native oxides. In this process, the Ge surface can be exposed to a solution of 1:10 (HF:H₂O) for about 30 seconds. Deionized (DI) water is then used to rinse the surface, followed by blow dry with a N₂ gun. The HF process can also temporarily passivate the dangling bonds on the surface. A concentration of less than 1:10 HF:H₂O can also be used and the exposure time can also be adjusted. In all the methods described herein, a spin rinse dryer (SRD) can be used to dry the surface.

In yet another example, an NH₄OH process can be used to chemically remove particles and strip oxide on the Ge surface. In this process, the Ge surface is placed in 1:1 (NH₄OH:H₂O) for about 120 seconds (2 minutes) and then rinsed by DI water. Then a 1:50 (HF:H₂O) solution is applied to the Ge surface for about 10 seconds, followed by rinsing with DI water. These two steps are then repeated, i.e., another 120 seconds in 1:1 (NH₄OH:H₂O) and rinse in DI water. The processes Ge surface is then blow dried with a N₂ gun. This NH₄OH process utilizes NH₄OH to remove particles and strip organics from the surface. The following HF step is used to strip the oxide from the surface and expose the bare Ge below.

In yet another example, a “Ge RCA+HNO₃” process can be used to process the Ge surface to chemically remove native oxide and then reform oxide. This process includes 60 seconds in 3:1 (NH₄OH:H₂O) followed by rinse in DI water. Then the Ge surface is exposed to 15 seconds in 1:6 (H₂O₂:H₂O) and another rinse in DI water. Next, pure (49%) HF is applied to the Ge surface for about 15 seconds, followed by DI water rinse. The process then proceeds to about 30 seconds in 1:4 (HC1:H₂O) and a third rinse in DI water. The Ge surface is then exposed to 15 seconds in pure HNO₃ and rinsed by DI water. Finally, an N₂ gun is used to dry the surface.

This “Ge RCA+HNO₃” process utilizes a modified RCA chemical clean to clean the surface of the Ge. A standard RCA clean may be too aggressive for Ge. Therefore this Ge RCA process can be employed as an alternative. The NH₄OH step can remove organics and reject particles. The H₂O₂ can oxidize the Ge surface and the HF can strip that oxide. The HCl solution can remove ions, then the HNO₃ chemically forms an oxide on the Ge surface. The chemical formation of an oxide can facilitate passivating the dangling bonds on the surface of the Ge, and can be a more controllable process than the formation of a native oxide from ambient exposure.

Forming Schottky Contacts Using Interlayers of Amorphous Silicon and HfO₂

Schottky contacts in a Ge photodetector can be formed by disposing a dielectric interlayer between the metal contacts and the Ge surface. This interlayer can reduce the density of metal-induced gap states and passivate dangling bonds on the Ge surface. Various materials can be used to form the interlayer, including amorphous Ge, silicon-carbon (SiC), Ge₃N₄, GeOₓ, sulfur, HfO₂, NiGe, and Al₂O₃, among others.

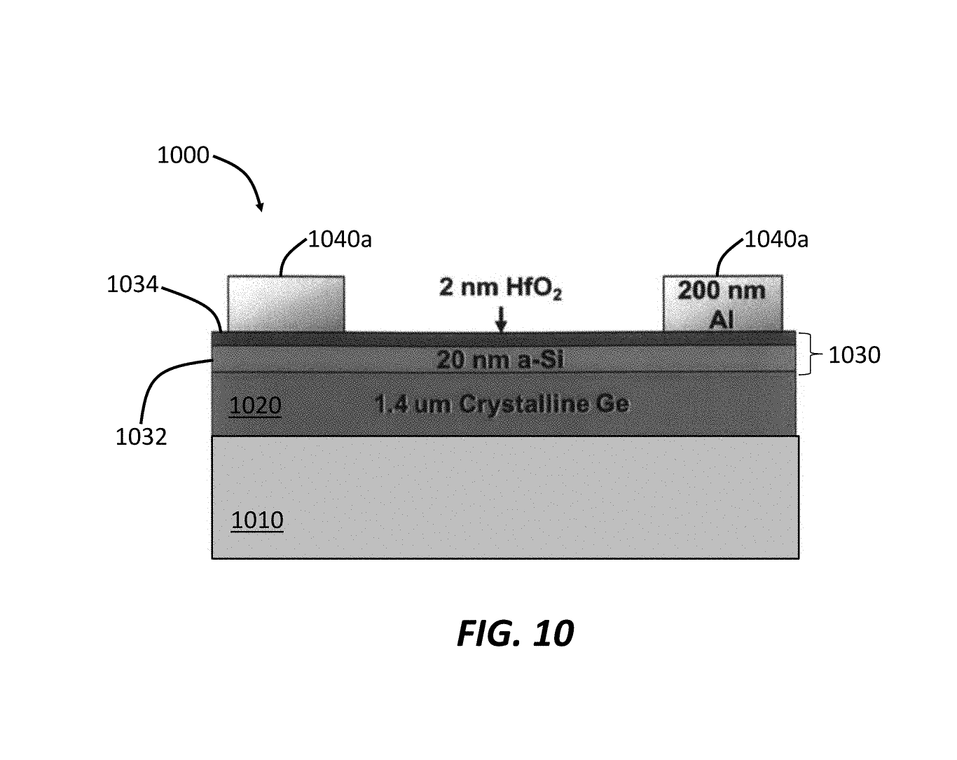

FIG. 10 shows a schematic of a Ge MSM photodetector 1000 using amorphous silicon and HfO₂ for the interlayer. The photodetector 1000 includes a crystalline Ge layer 1020 disposed on a substrate 1010. An interlayer 1030 is disposed on the Ge layer 1020, and two metal contacts 1040a and 1040b (e.g., Al contacts) are disposed on the interlayer 1030. The interlayer 1030 further includes an amorphous silicon layer 1032 disposed on the surface of the Ge layer 1020 and an HfO₂ layer 1034 disposed on the amorphous silicon layer 1032. The amorphous silicon layer 1032 can have a thickness of about 5 nm to about 30 nm (e.g., about 5 nm, about 10 nm, about 15 nm, about 20 nm, about 25 nm, or about 30 nm, including any values and sub ranges in between). The HfO₂ layer 1034 can have a thickness of about 0.5 nm to about 5 nm (e.g., about 0.5 nm, about 1.0 nm, about 1.5 nm, about 2.0. nm, about 2.5 nm, about 3.0 nm, about 3.5 nm, about 4.0 nm, about 4.5 nm, or about 5.0 nm, including any values and sub ranges in between).

The interlayer 1030 between the metal contacts 1040 and the Ge layer 1020 can reduce the metal induced gap states and relieve the Fermi level pinning. In order to reduce the density of interface states between the metal contacts 1040 and the surface of the Ge layer 1020, the dangling bonds on the Ge surface can be passivated by a dielectric layer. The inclusion of the amorphous silicon layer 1032 in the interlayer 1030 is fully compatible with standard CMOS processing. In addition, amorphous silicon can be deposited at low temperatures, thereby comply within the temperature constraints in BEOL processing. The purpose of the amorphous silicon layer 1032 is to passivate the dangling bonds on the surface of the Ge layer 1020.

The HfO₂ layer 1032 is added to passivate the surface of the amorphous silicon layer 1032. HfO₂ is also CMOS compatible, can be used as a high-κ gate dielectric, and can be deposited with an atomic layer deposition (ALD) technique. From a material perspective, the use of HfO₂ as a standard gate dielectric indicates that it already exists in mass-produced transistors and does not typically create interface states in Si between the amorphous silicon layer 1032 and the metal contacts 1030. From a processing perspective, the ability to be deposited with ALD means that very thin films can be deposited at low temperatures with excellent uniformity and atomic precision on film thickness.

During fabrication, the surface of the Ge layer 1020 can be cleaned before the formation of the interlayer 1030 and the metal contacts 1040. The treatment includes 10 minutes in 1:1 NH₄OH:H₂O, followed by 10 seconds in 1:50 HF:H₂O. These two steps are then repeated twice (i.e., a total of three rounds of NH₄OH and HF treatments). After the surface treatment, the amorphous silicon layer 1032 (e.g., about 20 nm thickness) can be deposited using PECVD. The wafer can be then immediately loaded into the ALD machine to deposit the HfO₂ layer 1032 (e.g., about 2 nm thick). After the ALD step, the wafer is immediately loaded into a sputtering tool to form the metal layer, such as an Al layer having a thickness of about 200 nm. The metal contacts 1040 can then be defined by photolithography and then the Al is dry etched with end point detection to stop the etch. An oxygen plasma is then used to remove the resist in an ashing process.

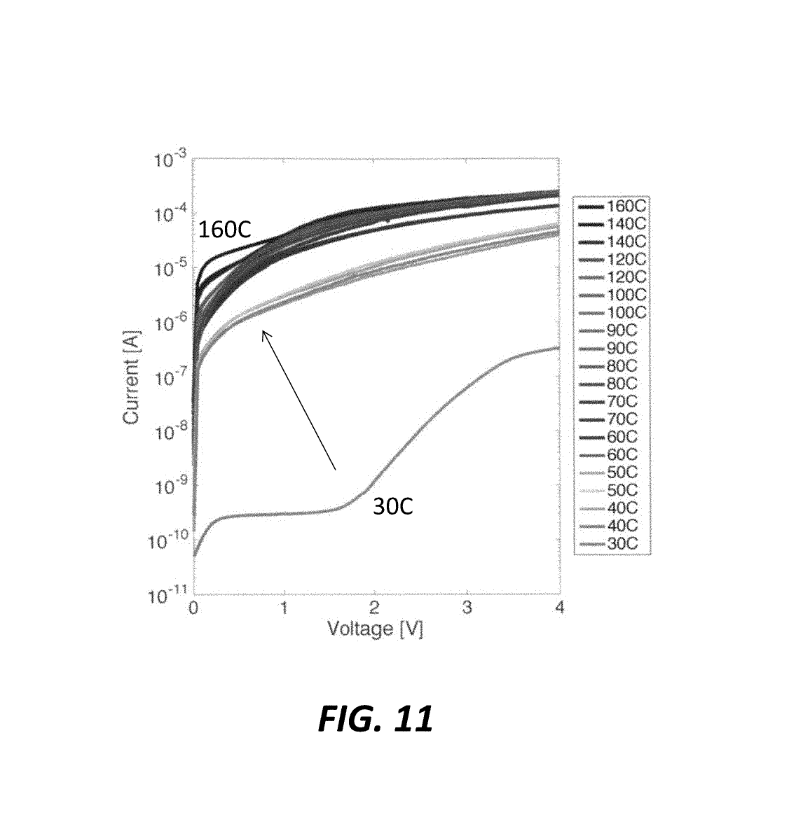

FIG. 11 shows measured dark currents as a function of voltage in a photodetector substantially similar to the photodetector 1000 shown in FIG. 10. Multiple sets of measurements were carried out at a variety of different temperatures ranging from 30° C. to 160° C. The device structure includes Al contacts on 2 nm of ALD HfO₂ disposed on 20 nm amorphous Si. The Ge layer has a thickness of about 1.4 μm. The initial measurements at 30° C. show promising signs that Schottky contacts are formed. The magnitude of the current at 30° C. remains at a low level (e.g., below 1 nA) for bias voltages up to 2 V. The low current and approximate linearity on the logarithmic scale indicate that the metal contact is rectifying and shows diode-like behavior. Increasing the temperature tends to reduce the rectifying effect, since thermionic emission over the Schottky barrier is a thermally activated process. At higher temperatures (e.g., higher than 70° C.), the dark current appears to saturate and no longer increases even the operating temperature increases.

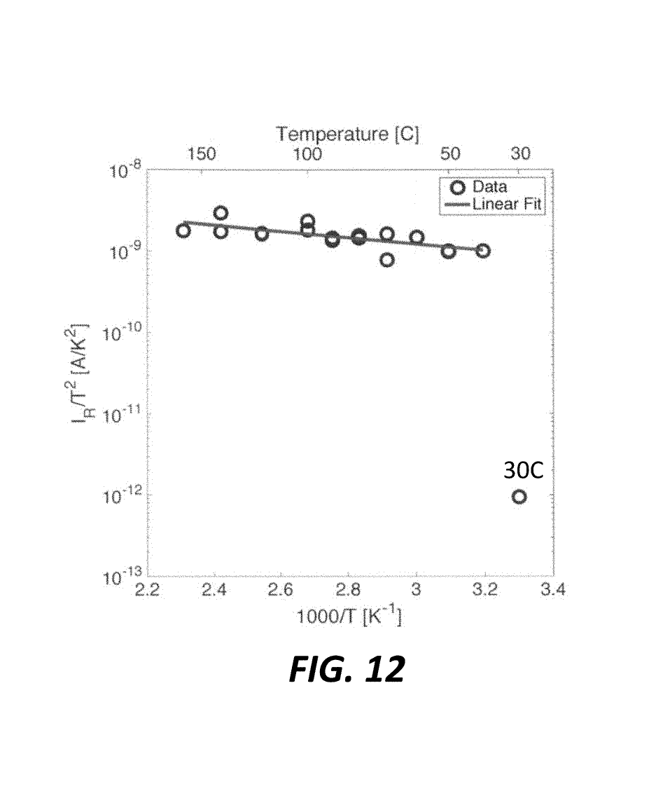

FIG. 12 shows Arrhenius plot of the dark I-V measurements shown in FIG. 11 to extract the Schottky barrier height. They axis in FIG. 12 is the reverse bias saturation current extracted from the I-V measurements in FIG. 11, and the x axis is the inverse of temperature. The data point taken at 30° C. is far away from the rest of the data points and the linear fitting. This data point has significantly lower dark current than the rest of the measurements and does not, fit, the linear approximation of the rest of the data. This indicates a shift in the results at temperatures above 30° C. The rest of the data is fit to a linear approximation in order to determine the slope of the line and extract the Schottky barrier height. The Schottky barrier was measured to be 0.08 eV. Therefore, the contact was a rectifying Schottky contact as fabricated, but may degrade to an Ohimic contact at high temperatures.

Forming Schottky Contacts Using Interlayers of Al₂O₃

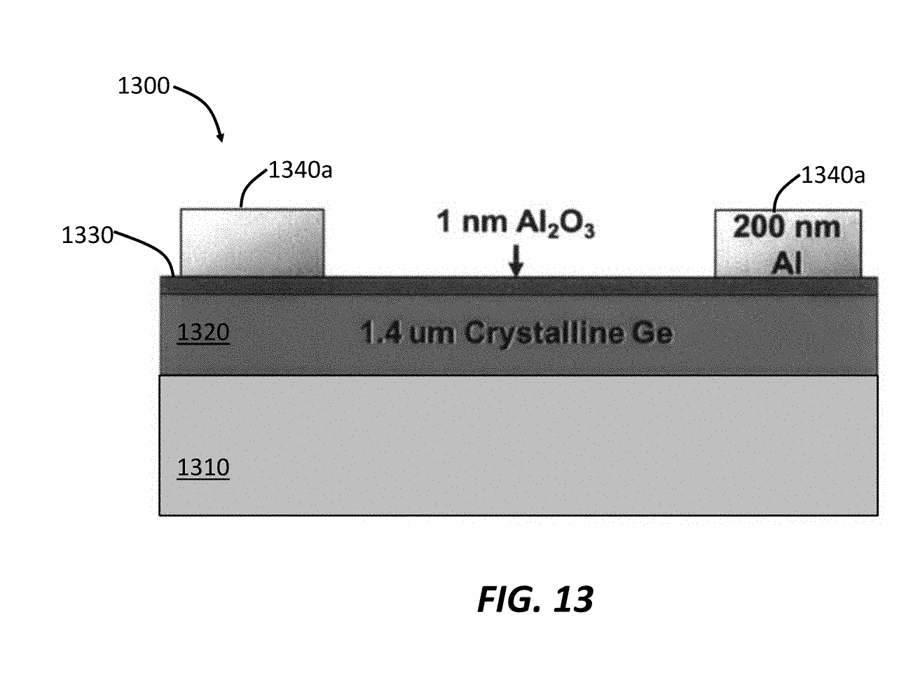

FIG. 13 shows a schematic of a Ge MSM photodetector 1300 using Al₂O₃ to form an interlayer 1330. The photodetector 1300 includes a crystalline Ge layer 1320 disposed on a substrate 1310. The interlayer 1330 is disposed on the Ge layer 1320 and two metal contacts 1340a and 1340b (e.g., Al contacts) are disposed on the interlayer 1330. The thickness of the interlayer 1330 can be substantially equal to or less than 5 nm (e.g., about 5 nm, about 4nm, about 3 nm, about 2.5 nm, about 2 nm, about 1.5 nm, about 1 nm, about 0.8 nm, about 0.5 nm, or less, including any values and sub ranges in between).

The Ge layer 1320 can be processed via a pre-metallization cleaning procedure before the interlayer 1330 is deposited. The processing can include 5 minutes in 1:5 H₂SO_{4 :}H₂O, and then 2 minutes in 1:4 H₂O₂:H₂O, followed by 15 seconds in 1:50 HF:H₂O. The purpose of the sulfuric acid step is to clean the organics from the surface. The peroxide chemically oxidizes the Ge surface, then the HF step etches away that oxide leaving a pristine Ge surface. After cleaning, the interlayer 1330 can be formed by depositing Al₂O₃ (e.g., about 1 nm thick) on the Ge layer 1320 using a plasma-enhanced ALD process at about 300° C.

Immediately after ALD step, the wafers can be loaded into a sputtering tool and an Al layer of about 200 nm thick can be deposited. The contacts 1340 are then defined by photolithography and dry etching the Al with end point detection. The photoresist can be then removed with an ashing process. The interlayer 1330 can be very thin (e.g., less than 3 nm) to allow carriers to effectively tunnel through the dielectric without restricting current flow. At the same time, the interlayer 1330 can still physically separate the metal contacts 1340 from the Ge layer 1320 so as to eliminate the Fermi-level pinning from metal induced gap states.

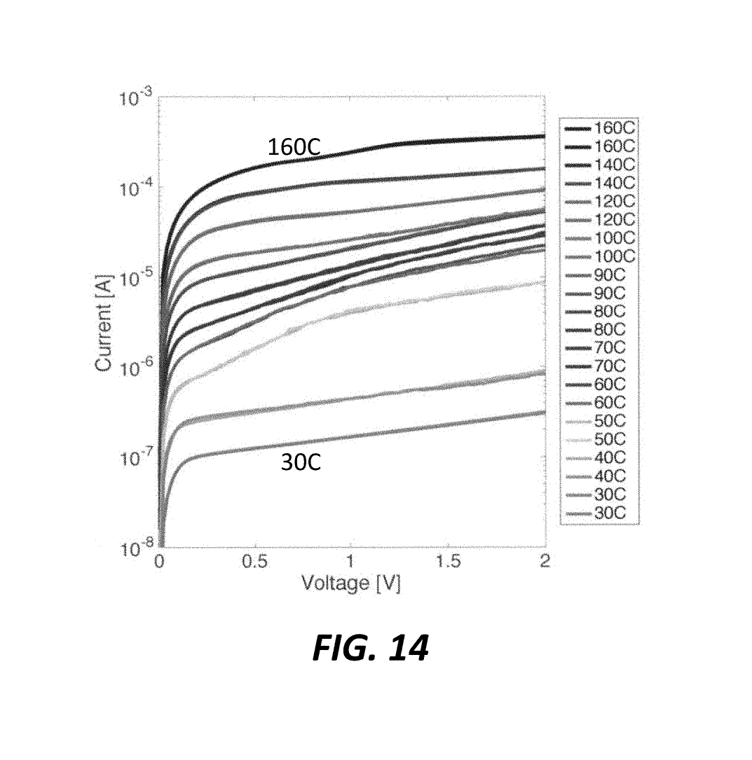

FIG. 14 shows dark I-V measurements at a variety of different temperatures ranging from about 30° C. to about 160° C. in a photodetector substantially similar to the photodetector 1300 shown in FIG. 13. The device structure includes Al contacts deposited on 1 nm of ALD Al₂O₃, which in turn is disposed on 1.4 μm crystalline Ge. The measurements taken at 30° C. show a dark current below 200 nA at biases up to 2 V. In addition, the relationship is linear when plotted on the logarithmic scale, which is a characteristic of Schottky diodes. The reverse bias leakage current is measured at a series of temperatures from 30° C. to 160° C.

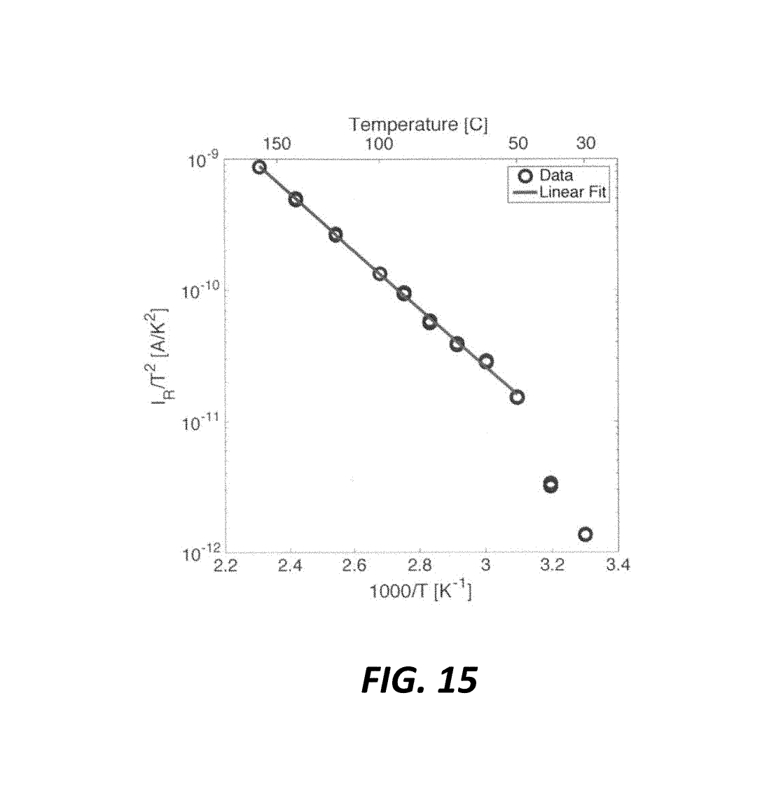

FIG. 15 shows an Arrhenius plot of the dark I-V measurements taken in FIG. 14 at a bias of 0.5 V. With a linear fit to the reverse bias current, the Schottky barrier height can be extracted. However, the reverse bias current does not saturate to a fixed value, but increases with increasing bias. Therefore extracting a reverse bias saturation current is dependent on the bias condition. For this specific example, the reverse bias of 0.5 V is used. The linear fit to the reverse bias current yields a Schottky barrier height of 0.44 eV. While FIG. 15 shows a reverse bias of 0.5 V to calculate the Schottky Barrier height, in practice, any other bias voltage can be used to perform the calculation.

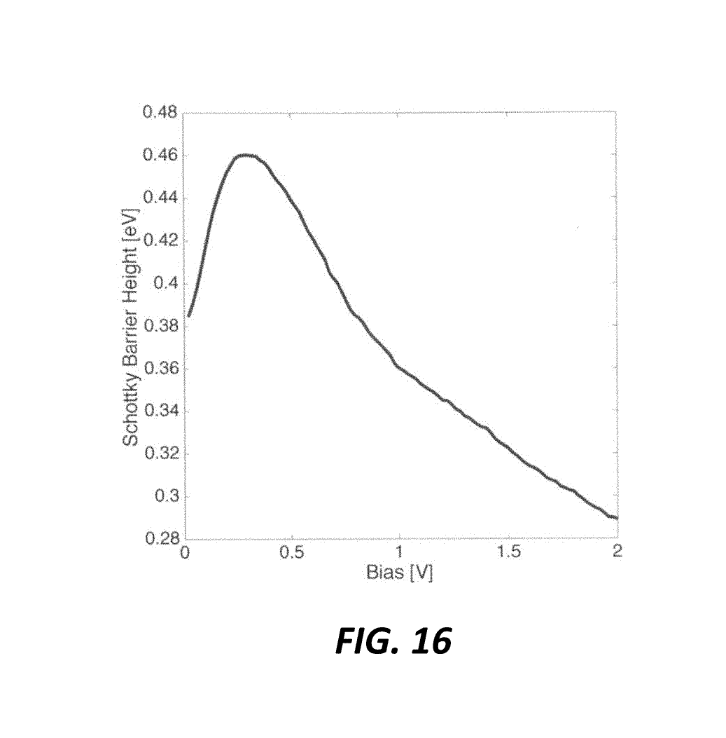

FIG. 16 is a plot showing calculated Schottky Barrier height as a function of bias voltages. The Schottky barrier is maximized at 0.46 eV at a small reverse bias of 0.25 V and decreases with increasing bias. The reduction in barrier height at low bias is likely an artifact since the Schottky diode is not expected to have reached a saturation current at very low biases. The reduction of barrier height with increasing bias may be attributed to image-force forces, and is usually known as Schottky-barrier lowering, or the Schottky effect.

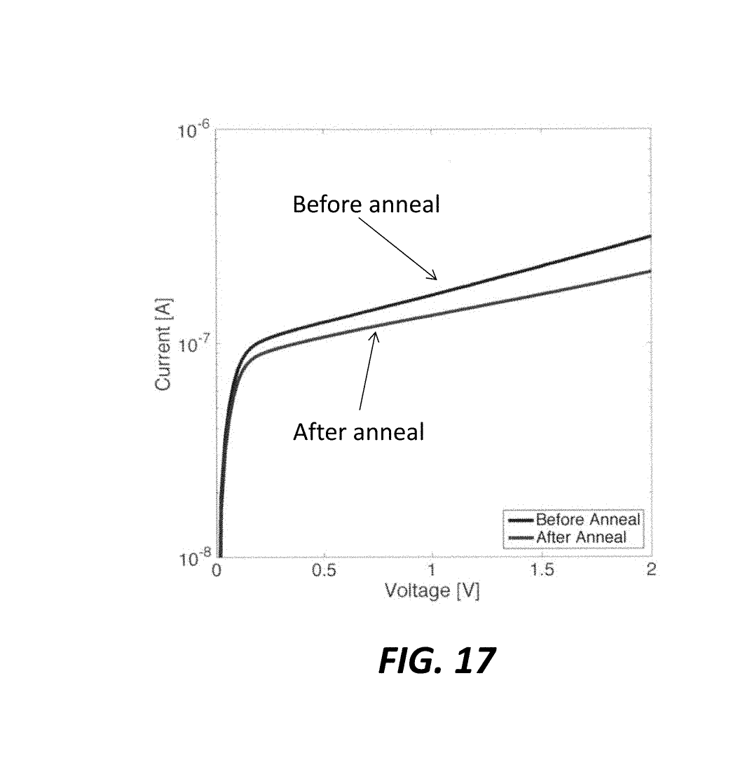

FIG. 17 shows dark I-V measurements before and after annealing at a temperature of about 160° C. When the device with an Al₂O₃ interlayer was measured before and after heat treatment, the dark current remained almost constant. The metal contact remains rectifying after exposure to elevated temperatures without a significant change in dark current. This verifies the thermal stability of this contact design, as 160° C. is higher temperature than the devices are expected to experience while integrated into a microprocessor.

Formation of Schottky Contacts with Improved Protection to Ge Surfaces

The metal contact design which utilizes a thin Al₂O₃ shown in FIG. 13 can alleviate Fermi level pinning and effectively suppress dark current. The dark current is dominated by thermionic emission over the Schottky barrier. Therefore, in the device 1300, only thermal emission over the Schottky barrier of 0.46 eV at low bias can generate dark current. An additional source of dark current includes the trap-assisted thermal generation from defect states within the band gap. If this generation occurs within the space charge region of the Schottky diode, the charges can be separated and contribute to the dark current.

Trap states within the band gap can arise from disruptions of the crystallinity of a semiconductor. Therefore, surfaces and structural defects can cause defect states, which can lead to increase Shockley-Read-Hall recombination. The recombination, in turn, can reduce the responsivity of a photodetector or trap assisted thermal generation, thereby increasing the dark current of the resulting photodetector. While defects in the semiconductor can arise from the growth process or from significant strain in the material, they can also be introduced from processing.

The process described above (e.g. with reference to FIG. 13) for producing Schottky barriers to Ge includes a plasma etch step to etch the Al and define the metal contacts. This etch step ends with an endpoint detection. Therefore, at the end of the Al plasma etch, the Al₂O₃ may be exposed to the etching plasma. While the etch chemistry is selective to Al, accidental damage to the Al₂O₃ may still occur. Damages to the Al₂O₃ can expose the underlying Ge surface to the etch plasma, since the Al₂O₃ layer is usually very thin. The plasma contains ionized particles which are accelerated towards the wafer surface in order to yield an anisotropic etch. These ionized particles can cause structural damage on the Ge surface and introduce trap states along the Ge surface, thereby reducing device performance.

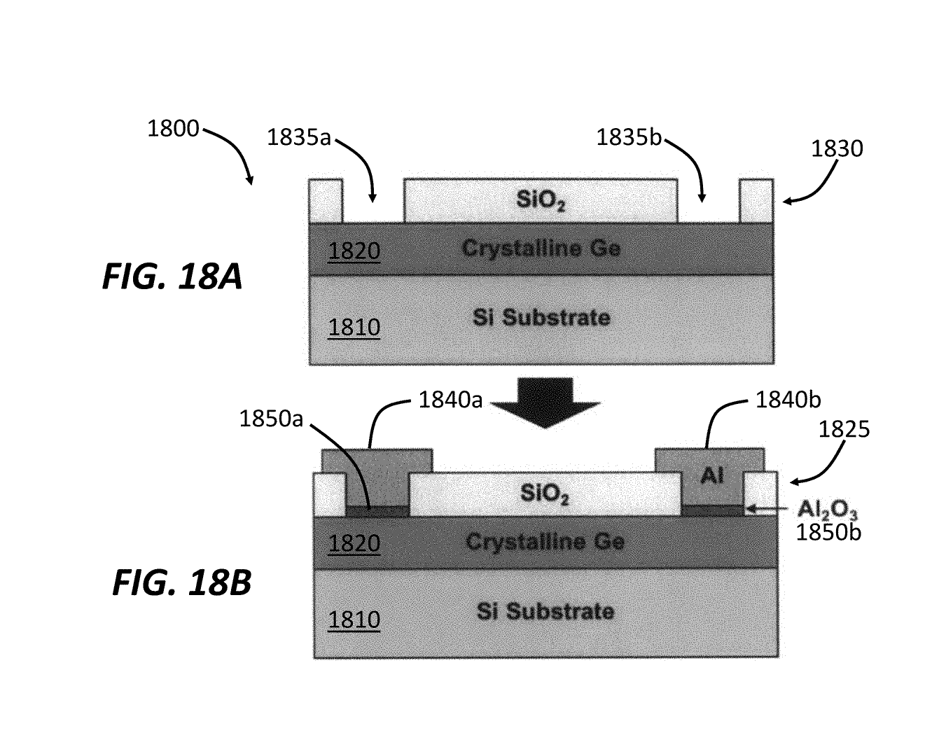

FIGS. 18A and 18B illustrate a method 1800 to form Schottky contacts with improved protection to the Ge surface. Before metallization, a protective SiO₂ film 1830 is disposed on the Ge layer 1820, which in turn is disposed on a substrate 1810. Then contact vias 1835a and 1835b (collectively referred to as contact vias 1835) are etched in the SiO₂ layer 1830, as shown in FIG. 18A. The contact vias 1835 can be formed using, for example, HF. HF is usually gentle on the Ge surface and does not cause damages to the Ge surface.

Interlayers 1850a and 1850b are then deposited via ALD into the vias 1835a and 1835b, respectively. The interlayers 1850a and 1850b can include, for example, Al₂O₃, or any other appropriate material. A metal film is then deposited, filling the rest of the vias 1835 and covering the surface of the SiO₂ layer 1830. Metal contacts 1840a and 1840b can be then formed via dry etching as described above. When the metal film is etched, the end-point ends on the protective SiO₂ layer 1830, while the underneath Ge layer 1820 remains buried and protected. The method 1800 can reduce the creation of trap states near the Ge surface, thereby further decreasing dark current and increasing photocurrent.

Characterizations of Ge MSM Photodetectors

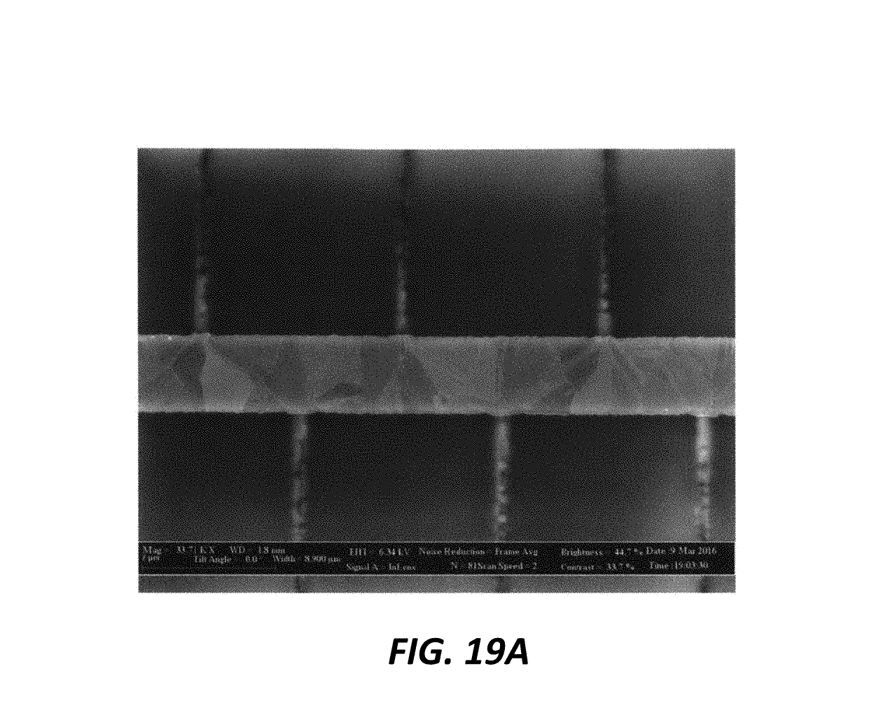

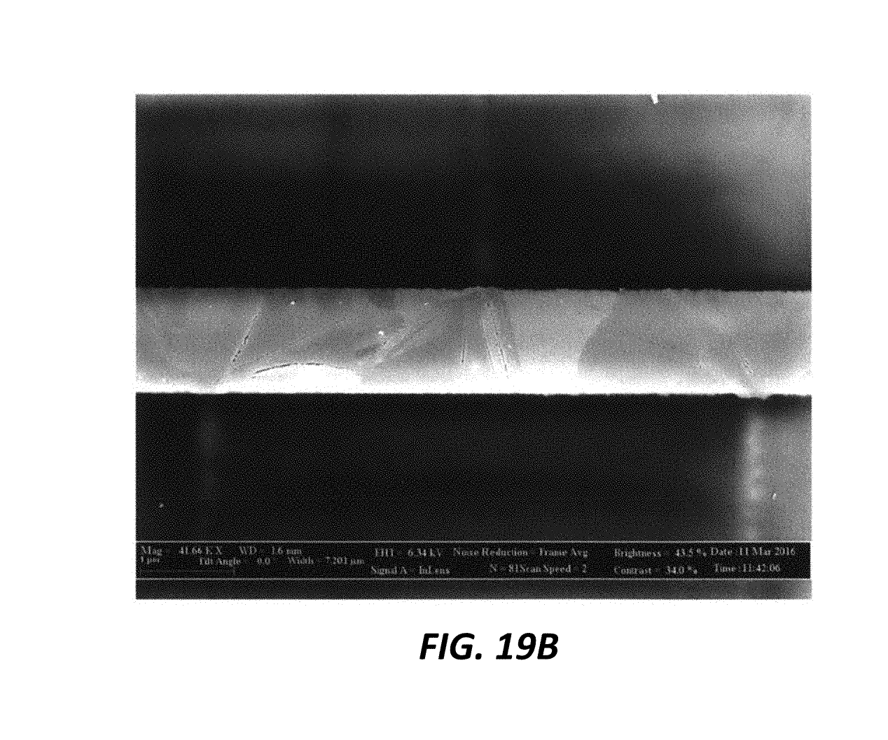

FIG. 19A shows an SEM image of a trench filled with crystalline Ge after chemical and mechanical planarization (CMP). The image was taken immediately after Ge growth. The fabrication of the structure in FIG. 19A is as follows. Large-grain Ge are grown on amorphous substrates, while adhering to low-temperature processing constraints (below 450° C.). The grains are then coalesced to form a continuous material within a lithographically defined 1 μm wide trench. These coalesced grains have a rough surface morphology with significant overgrowth over the Ge trench. Long range faceting was observed, indicating large grains. During the coalescence process, the Ge significantly overgrows the shallow 300 nm deep trenches, resulting in a very rough surface morphology.

The Ge grains overgrow the oxide trench in the lateral dimension as well as the vertical dimension. A CMP process was used to create a planar surface for the metallization process and to precisely define the active area of Ge devices, such as photodetectors. Immediately after the CMP step, the trenches are well filled with coalesced Ge and planar, as seen in FIG. 19A.

FIG. 19B shows an SEM image of the structure shown in FIG. 19A immediately after post-CMP cleaning in dilute H₂SO₄ and HF. Slight surface damage is observed where cleaning procedure has begun to attack some grain boundaries and specific facets. The CMP process involves direct physical contact with the top surface of the wafer and direct contact with the active Ge material. This direct contact may lead to contamination of the active material. Therefore it can be helpful to clean the device to remove the remaining CMP slurry particles, any organic contamination, and any additional contamination that may degrade the performance of the detectors.

A modified piranha clean was utilized which consisted of 5min in 1:5 H₂SO_{4:}H₂O, then 15 sec in 1:50 HF:H₂O. After this cleaning step, the devices were imaged again. The post-CMP cleaning step caused slight damage to the Ge surface, as seen in FIG. 19B. The damage appears to be isolated to grain boundaries or certain specific grain facet orientations. This effect may be caused by the large strain in these devices, especially concentrated at grain boundaries, or the exposure of facets with high surface energies. These strained and high energy facets may be less stable and therefore facilitate the slight etch damage from the cleaning process.

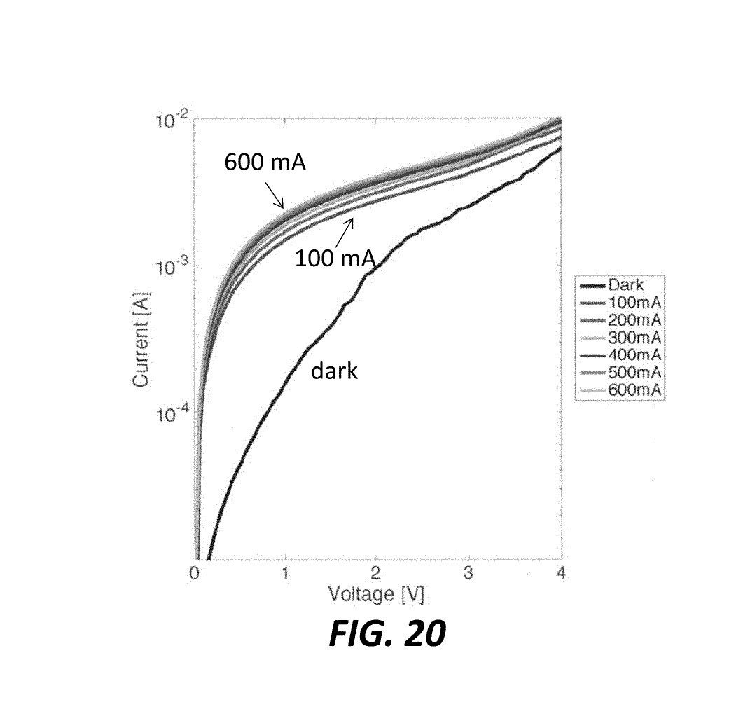

FIG. 20 shows measured dark I-V curves for a 75 μm long MSM photodetector with a contact separation of 2 μm. Illumination at 980 nm is used and the legend denotes the current used to drive the laser. The significant increase in current is due to the generation of a photocurrent, and therefore the MSM structure is acting as an effective photodetector.

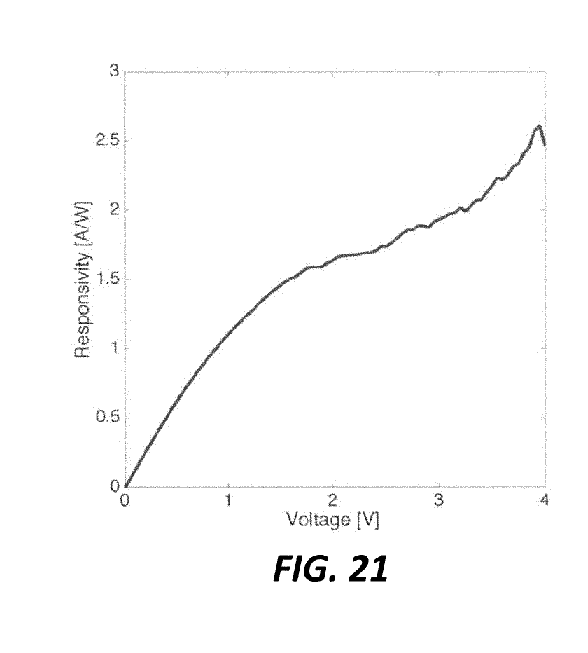

FIG. 21 shows measured responsivity of MSM photodetectors grown on geometrically confined structures on amorphous substrates. Despite the leakage current present in the detectors on amorphous substrates, very large responsivities were still measured. For a device with a contact spacing of 1 μm, a maximum responsivity of 2.5 A W⁻¹ was measured at a bias of 4 V. The magnitude of the measured responsivity of these detectors demonstrate the presence of gain with a total internal quantum efficiency up to 315%. Therefore, these detectors demonstrate a proof of concept for high performance Ge MSM photodetectors on amorphous substrates which are fully compatible with back end of line integration with standard CMOS processing.

Conclusion

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize, or be able to ascertain using no more than routine experimentation, many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

Also, various inventive concepts may be embodied as one or more methods, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of” or “exactly one of” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

1. An apparatus, comprising:
a first strip comprising crystalline germanium and extending along a first direction;
at least one second strip comprising germanium and extending along a second direction different from the first direction, the at least one second strip having a first end in contact with the first strip and a second end opposite the first end;
a growth seed comprising amorphous silicon, disposed at the second end of the second strip, to grow the at least one second strip and at least a portion of the first strip;
a first electrode disposed on the first strip; and
a second electrode disposed on the first strip.

2. The apparatus of claim 1, wherein the first strip has a width of about 100 nm to about 2 μm.

3. The apparatus of claim 1, wherein a distance between the first electrode and the second electrode is about 100 nm to about 5 μm.

4. The apparatus of claim 1, wherein the at least one second strip comprises:
a first side strip extending from a first side of the first strip; and
a second side strip extending from a second side, opposite the first side, of the first strip, the first side strip being offset from the second side strip.

5. The apparatus of claim 4, wherein the first electrode is disposed between the first side strip and the second side strip.

6. The apparatus of claim 1, wherein the at least one second strip comprises:
a first periodic array of side strips extending from a first side of the first strip; and
a second periodic array of side strips extending from a second side, opposite the first side, of the first strip, the first periodic array of side strips being staggered with respect to the second periodic array of side strips.

7. The apparatus of claim 6, wherein the first periodic array of side strips and the second periodic array of side strips have a pitch of about 200 nm to about 2 μm.

8. The apparatus of claim 1, wherein the at least one second strip has a length and a width, and a ratio of the length to the width is about 1.5 to about 3.

9. The apparatus of claim 1, wherein the at least one second strip has a first height less than a second height of the first strip, and the apparatus further comprises:
a SiO₂ layer substantially encapsulating the at least one second strip.

10. The apparatus of claim 1, wherein at least one of the first electrode or the second electrode comprises a Schottky contact.

11. The apparatus of claim 10, wherein the Schottky contact comprises:
an insulating interlayer disposed on the first strip; and
a metal contact disposed on the insulating interlayer.

12. The apparatus of claim 11, wherein the insulating interlayer comprises Al₂O₃ and has a thickness substantially equal to or less than 5 nm.

13. An apparatus comprising:
a strip of crystalline germanium extending along a first direction, the strip having a plurality of grain boundaries distributed along the first direction;
a first electrode disposed above a first grain boundary in the plurality of grain boundaries; and
a second electrode disposed on the strip.

14. The apparatus of claim 13, wherein a distance between the grain boundary and a second grain boundary, adjacent the first grain boundary in the plurality of grain boundaries, is about 100 nm to about 2 μm.

15. The apparatus of claim 13, wherein the second electrode is disposed above a second grain boundary, adjacent to the first grain boundary, in the plurality of grain boundaries.

16. The apparatus of claim 13, wherein the second electrode is disposed above a region defined by the first grain boundary and a second grain boundary adjacent to the first grain boundary.

17. The apparatus of claim 13, further comprising:
an insulating interlayer disposed between the first electrode and the strip of crystalline germanium.

18. The apparatus of claim 17, wherein the insulating interlayer has a thickness substantially equal to or less than 5 nm.

19. A method of growing crystalline germanium on amorphous silicon, the method comprising:
forming a channel structure in a SiO₂ layer, the channel structure comprising:
a trench along a first direction in the SiO₂ layer; and
an array of seed channels extending from the trench and along a second direction different from the first direction, each seed channel having a first end coupled to the trench and a respective growth seed disposed at a second end opposite the first end, the respective growth seed comprising amorphous silicon; and
growing the crystalline germanium in the trench based on at least in part on the respective growth seed in each seed channel.

20. The method of claim 19, wherein forming the channel structure comprises:
forming an array of seed strips along the second direction on a substrate, the array of seed strips comprising amorphous silicon;
forming the SiO₂ layer on the array of seed strips;
etching the SiO₂ layer to define the trench in the SiO₂ layer extending along the first direction; and
etching a portion of each seed strip in the array of seed strips to form the array of seed channels.

21. The method of claim 20, wherein forming the array of seed strips comprises:
depositing an amorphous silicon layer on the substrate, the amorphous silicon layer having a thickness substantially equal to or less than 100 nm; and
selectively etching the amorphous silicon layer to form the array of seed strips.

22. The method of claim 20, wherein forming the SiO₂ layer comprises depositing the SiO₂ layer via plasma enhanced chemical vapor deposition (PECVD), the SiO₂ layer having a thickness of about 100 nm to about 5 μm.

23. The method of claim 20, wherein etching the array of seed strips comprises applying a tetramethylammonium hydroxide (TMAH) wet etch on the array of seed strips.

24. The method of claim 19, wherein growing the crystalline germanium comprises growing the crystalline germanium using an ultra-high vacuum chemical vapor deposition (UHVCVD) at a temperature substantially equal to or less than 450° C.

25. The method of claim 19, wherein growing the crystalline germanium comprises forming a first strip comprising the crystalline germanium filling the trench, and the method further comprises:
depositing Al₂O₃ on the first strip to form an insulating interlayer having a thickness substantially equal to or less than 2 nm.

26. The method of claim 25, wherein growing the crystalline germanium further comprises forming a plurality of grain boundaries in the first strip, and the method further comprises:
depositing a first electrode on the first strip above a first grain boundary in the plurality of grain boundaries; and
depositing a second electrode on the first strip above a second grain boundary, adjacent to the first grain boundary, in the plurality of grain boundaries.
